(19) United States
(12) Patent Application Publication
(10) Pub. No.: US 2024/0203966 A1
(43) Pub. Date: Jun. 20, 2024

(54) DISPLAY DEVICE AND MANUFACTURING METHOD THEREOF

(71) Applicant: Samsung Display Co., LTD., Yongin-si (KR)

(72) Inventors: Sung Geun BAE, Yongin-si (KR); Jang Soon PARK, Yongin-si (KR); Tae Hee LEE, Yongin-si (KR); Hyun Wook LEE, Yongin-si (KR); Da Sol JEONG, Yongin-si (KR)

(73) Assignee: Samsung Display Co., LTD., Yongin-si (KR)

(21) Appl. No.: 18/364,551

(22) Filed: Aug. 3, 2023

(30) Foreign Application Priority Data
Dec. 15, 2022 (KR) 10-2022-0176073

(51) Int. Cl. H01L 25/16; H01L 27/12

(52) U.S. Cl. CPC H01L 25/167; H01L 27/1259

(57) ABSTRACT

A display device includes sub-alignment areas including a pathway area defined by a first adjacent electrode and a second adjacent electrode spaced apart from each other in a first direction. A pathway area includes a first pathway area and a second pathway area spaced apart from each other along a second direction different from the first direction. The first adjacent electrode of the first pathway area and the first adjacent electrode of the second pathway area are spaced apart from each other with an open area therebetween. The second adjacent electrode of the first pathway area and the second adjacent electrode of the second pathway area are spaced apart from each other with the open area therebetween.

### CROSS-REFERENCE TO RELATED APPLICATION(S)

This application claims priority to and benefits of Korean Patent Application No. 10-2022-0176073 under 35 U.S.C. §119 filed in the Korean Intellectual Property Office on Dec. 15, 2022, the entire contents of which are incorporated herein by reference.

### BACKGROUND

### 1. Technical Field

The disclosure relates to a display device and a manufacturing method thereof.

### 2. Description of the Related Art

Recently, as interest in an information display is increasing, research and development for display devices are continuously conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An object of the disclosure is to provide a display device with improved process efficiency and a manufacturing method thereof.

The technical objectives to be achieved by the disclosure are not limited to those described herein, and other technical objectives that are not mentioned herein would be clearly understood by a person skilled in the art from the description of the disclosure.

An embodiment of the disclosure provides a display device that may include electrodes disposed on a base layer and including a body electrode and a branch electrode electrically connected to the body electrode, the branch electrode may include adjacent electrodes including a first adjacent electrode and a second adjacent electrode; and light emitting elements disposed in an alignment area including sub-alignment areas disposed on the base layer and disposed between the first adjacent electrode and the second adjacent electrode. Each of the sub-alignment areas may include a pathway area defined by the first adjacent electrode and the second adjacent electrode spaced apart from each other in a first direction. The pathway area may include a first pathway area and a second pathway area spaced apart from each other in a second direction different from the first direction. The first adjacent electrode of the first pathway area and the first adjacent electrode of the second pathway area may be spaced apart from each other with an open area between the first adjacent electrode of the first pathway area and the first adjacent electrode of the second pathway area. The second adjacent electrode of the first pathway area and the second adjacent electrode of the second pathway area may be spaced apart from each other with the open area between the second adjacent electrode of the first pathway area and the second adjacent electrode of the second pathway area.

The alignment area may extend in the first direction. The alignment area may include a first alignment area and a second alignment area adjacent to each other in the second direction.

The body electrode in the first alignment area and the body electrode in the second alignment area may be separated from each other.

The sub-alignment areas may include a first sub-alignment area and a second sub-alignment area. The branch electrode may include a connecting branch electrode electrically connecting the adjacent electrode in the first sub-alignment area and the adjacent electrode in the second sub-alignment area. The connecting branch electrode may include a first connecting branch electrode and a second connecting branch electrode. The body electrode may include a first body electrode and a second body electrode. The first body electrode, the first adjacent electrode, and the first connecting branch electrode may be integral with each other. The second body electrode, the second adjacent electrode, and the second connecting branch electrode may be integral with each other.

The first connecting branch electrode may electrically connect the first adjacent electrode and the first body electrode disposed in the first pathway area in the second sub-alignment area. The second connecting branch electrode may electrically connect the second adjacent electrode and the second body electrode disposed in the second pathway area in the first sub-alignment area.

The display device may further include a bank surrounding at least a portion of the pathway area and overlapping the connecting branch electrode in a plan view. The open area may not overlap the bank in a plan view.

The sub-alignment areas may include a first sub-alignment area and a second sub-alignment area adjacent to each other in the first direction. The light emitting element may include first light emitting elements disposed in the first pathway area to form a first light emitting part and second light emitting elements disposed in the second pathway area to form a second light emitting part. The light emitting element in the first sub-alignment area and the light emitting element in the second sub-alignment area may form a sub-pixel. The display device may further include an anode connecting electrode, a first intermediate connecting electrode, a second intermediate connecting electrode, a third intermediate connecting electrode, and a cathode connecting electrode. The anode connecting electrode, the first light emitting part in the first sub-alignment area, the first intermediate connecting electrode, the second light emitting unit in the first sub-alignment area, the second intermediate connecting electrode, the second light emitting part in the second sub-alignment area, the third intermediate connecting electrode, the first light emitting part in the second sub-alignment area, and the cathode connecting electrode may be sequentially electrically connected.

The first intermediate connecting electrode may overlap the open area in the first sub-alignment area in a plan view, and the third intermediate connecting electrode may overlap open area in the second sub-alignment area in a plan view.

The open area may not overlap the light emitting element in a plan view.

The display device may further include sub-pixels each including the light emitting element. The sub-alignment areas may include a first sub-alignment area and a second sub-alignment area adjacent to each other in the first direction. The first sub-alignment area and the second sub-alignment area may correspond to one of the sub-pixels.

The display device may further include a first sub-pixel emitting light of a first color and a second sub-pixel emitting light of a second color, each of the first sub-pixel and the second sub-pixel including the light emitting element. The sub-alignment areas may include a first sub-alignment area and a second sub-alignment area adjacent to each other in the first direction. The first sub-alignment area may correspond to the first sub-pixel. The second sub-alignment area may correspond to the second sub-pixel.

The body electrode may extend in the first direction from a first end portion of the light emitting element toward a second end portion of the light emitting element. The adjacent electrode may extend in the second direction.

An embodiment of the disclosure provides a display device that may include alignment areas including a first alignment area and a second alignment area that extend along a first direction and are spaced apart from each other along a second direction different from the first direction; electrodes, at least some of which are disposed within the alignment areas, including body electrodes and branch electrodes , at least part of the electrodes being disposed within the alignment areas electrically connected to the body electrodes; and light emitting elements disposed in the alignment areas. The body electrodes may extend in the first direction. The body electrodes in the first alignment area and the body electrodes in the second alignment area may be separated from each other. The branch electrodes may include connecting branch electrodes extending in the second direction.

An embodiment of the disclosure provides a manufacturing method of a display device, that may include patterning electrodes including body electrodes and branch electrodes disposed on a base layer; and disposing a light emitting element on an adjacent one of the branch electrodes in an alignment area. The alignment area may include sub-alignment areas. Each of the sub-alignment areas may include a first pathway area and a second pathway area. The adjacent electrode may include a first adjacent electrode and a second adjacent electrode. The first adjacent electrode of the first pathway area and the first adjacent electrode of the second pathway area may be spaced apart from each other with an open area between the first adjacent electrode of the first pathway area and the first adjacent electrode of the second pathway area. The second adjacent electrode of the first pathway area and the second adjacent electrode of the second pathway area may be spaced apart from each other with the open area between the second adjacent electrode of the first pathway area and the second adjacent electrode of the second pathway area.

The body electrodes may include a first body electrode and a second body electrode. The first body electrode may be electrically connected to the first adjacent electrode. The second body electrode may be electrically connected to the second adjacent electrode. The disposing of the light emitting element may include applying a first alignment signal to the first adjacent electrode through the first body electrode; and applying a second alignment signal to the second adjacent electrode through the second body electrode.

The sub-alignment areas may include a first sub-alignment area and a second sub-alignment area adjacent in a first direction. The body electrodes may be disposed throughout the first sub-alignment area and the second sub-alignment area in the first direction.

The manufacturing method may further include forming a bank protruding in a thickness direction of the base layer on the base layer. The branch electrode may further include a connecting branch electrode electrically connecting the adjacent electrode in the first sub-alignment area and the adjacent electrode in the second sub-alignment area. The open area may not overlap the bank in a plan view. The connecting branch electrode may overlap the bank in a plan view.

The disposing of the light emitting element may include aligning the light emitting element based on an electric field formed between the first adjacent electrode and the second adjacent electrode. The aligning of the light emitting element may include aligning the light emitting element between the first adjacent electrode and the second adjacent electrode without aligning it in the open area.

The first adjacent electrode and the second adjacent electrode may be spaced apart from each other along the first direction. The first pathway area and the second pathway area may be spaced apart from each other in a second direction different from the first direction. A first alignment signal may be applied to the first adjacent electrode of the first pathway area and the first adjacent electrode of the second pathway area. A second alignment signal may be applied to the second adjacent electrode of the first pathway area and the second adjacent electrode of the second pathway area.

The manufacturing method may further include forming a connecting electrode layer. The connecting electrode layer may include an anode connecting electrode electrically connected to the light emitting element, an intermediate connecting electrode electrically connected to the light emitting element and overlapping the open area in a plan view, and a cathode connecting electrode electrically connected to the light emitting element.

According to an embodiment of the disclosure, a display device with improved process efficiency and a manufacturing method thereof may be provided.

### BRIEF DESCRIPTION OF THE DRAWINGS

The above and other objects and features of the disclosure will become apparent by describing in detail embodiments thereof with reference to the accompanying drawings in which:

FIG. 1 illustrates a schematic perspective view of a light emitting element according to an embodiment.

FIG. 2 illustrates a schematic cross-sectional view of a light emitting element according to an embodiment.

FIG. 3 illustrates a schematic top plan view of a display device according to an embodiment.

FIG. 4 illustrates a pixel circuit included in a sub-pixel according to an embodiment.

FIG. 5 illustrates a schematic block diagram of a structure in which an alignment signal is supplied according to an embodiment.

FIG. 6 illustrates a schematic top plan view of a display device according to an embodiment.

FIG. 7 illustrates a schematic top plan view of a display device according to an embodiment.

FIG. 8 illustrates a schematic top plan view of a structure including an open area according to an embodiment.

FIG. 9 illustrates a schematic cross-sectional view taken along line A-A′ of FIG. 7.

FIG. 10 illustrates a schematic top plan view of a display device according to an embodiment.

FIG. 11 illustrates a schematic top plan view of a display device according to an embodiment.

FIG. 12 illustrates a schematic cross-sectional view taken along line B-B′ of FIG. 11.

FIG. 13 illustrates a schematic cross-sectional view of a pixel according to an embodiment.

FIG. 14 and FIG. 15 illustrate schematic top plan views of process steps of a manufacturing method of a display device according to an embodiment.

### DETAILED DESCRIPTION OF THE EMBODIMENTS

Since the disclosure may be variously modified and have various forms, embodiments will be illustrated and described in detail in the following. This, however, by no means restricts the disclosure to the specific embodiments, and it is to be understood as embracing all included within the spirit and scope of the disclosure changes, equivalents, and substitutes thereof.

In the drawings, sizes, thicknesses, ratios, and dimensions of the elements may be exaggerated for ease of description and for clarity. Like numbers refer to like elements throughout.

Terms such as first, second, and the like will be used only to describe various constituent elements, and are not to be interpreted as limiting these constituent elements. The terms are only used to differentiate one constituent element from other constituent elements. For example, a first constituent element could be termed a second constituent element, and similarly, a second constituent element could be termed as a first constituent element, without departing from the scope of the disclosure.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the disclosure, it should be understood that the terms “comprises,” “comprising,” “includes,” and/or “including,”, “has,” “have,” and/or “having,” and “configure” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be understood that when an element such as a layer, film, region, area, or substrate is referred to as being “on” another element, it can be directly on the other element or intervening elements may also be present. In the specification, when a portion of a layer, film, region, area, plate, or the like is referred to as being formed “on” another portion, the formed direction is not limited to an upper direction but includes a lateral or lower direction. In contrast, when an element of a layer, film, region, area, plate, or the like is referred to as being “below” another element, it may be directly below the other element, or intervening elements may be present.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. The term “overlap” or “overlapped” means that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

Unless otherwise defined or implied herein, all terms (including technical terms and scientific terms) used in the specification have the same meaning as commonly understood by one skilled in the art to which the disclosure belongs. Terms such as terms defined in the dictionaries commonly used should be interpreted as having a meaning consistent with the meaning in the context of the related technology, and should not be interpreted in ideal or overly formal meanings unless explicitly defined herein.

The disclosure relates to a display device and a manufacturing method thereof. Hereinafter, a display device and a manufacturing method thereof according to an embodiment will be described with reference to the accompanying drawings.

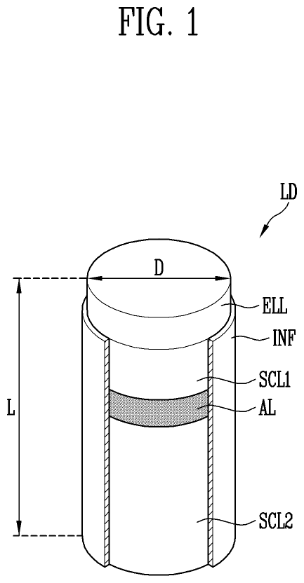

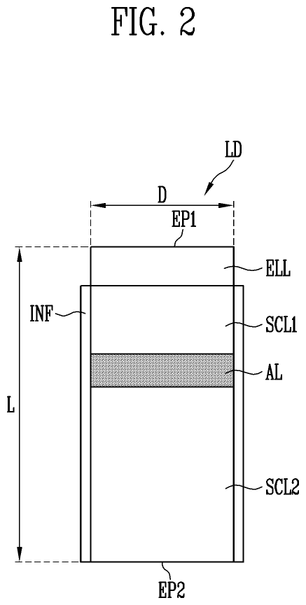

First, a light emitting element LD according to an embodiment will be described with reference to FIG. 1 to FIG. 2. FIG. 1 illustrates a schematic perspective view of a light emitting element according to an embodiment. FIG. 2 illustrates a schematic cross-sectional view of a light emitting element according to an embodiment.

The light emitting element LD emits light. The light emitting element LD may include a first semiconductor layer SCL1, a second semiconductor layer SCL2, and an active layer AL disposed between the first semiconductor layer SCL1 and the second semiconductor layer SCL2. According to an embodiment, the first semiconductor layer SCL1, the active layer AL, and the second semiconductor layer SCL2 may be sequentially stacked each other along a direction of a length L of the light emitting element LD. According to an embodiment, the light emitting element LD may further include an electrode layer ELL and an insulating film INF.

The light emitting element LD may have various shapes. For example, the light emitting element LD may have a cylindrical shape extending in one direction or a direction. The “cylindrical shape” may include a rod-like shape or bar-like shape (for example, with an aspect ratio greater than 1) that is long in the length L direction, such as a circular cylinder or a polygonal cylinder, but a shape of a cross-section thereof is not particularly limited.

The light emitting element LD may have a first end portion EPI and a second end portion EP2. According to an embodiment, the first semiconductor layer SCL1 may be adjacent to a first end portion EP1 of the light emitting element LD, and the second semiconductor layer SCL2 may be adjacent to a second end portion EP2 of the light emitting element LD. According to an embodiment, the electrode layer ELL may be adjacent to the first end portion EP1.

The light emitting element LD may be manufactured by etching sequentially stacked semiconductor layers. The light emitting element LD may have a size of a nano-scale to a micro-scale. For example, a diameter D (or a width) of the light emitting element LD and the length L of the light emitting element LD may each have a nano scale or a micro scale. However, the disclosure is not necessarily limited thereto.

The first semiconductor layer SCL1 may include a first conductive semiconductor. The first semiconductor layer SCL1 is disposed to on the active layer AL, and may include a semiconductor layer of a type different from that of the second semiconductor layer SCL2. For example, the first semiconductor layer SCL1 may include a P-type semiconductor layer. For example, the first semiconductor layer SCL1 may include at least one semiconductor material of InAlGaN, GaN, AlGaN, InGaN, AIN, and InN, and may include a P-type semiconductor layer doped with a first conductive dopant such as Ga, B, and Mg. However, the disclosure is not limited to the above-described examples. The first semiconductor layer SCL1 may include various materials.

The active layer AL may be disposed between the first semiconductor layer SCL1 and the second semiconductor layer SCL2. The active layer AL may include a single-quantum well or multi-quantum well structure. The position of the active layer AL is not limited to a specific example, and may be variously changed according to a type of the light emitting element LD.

A clad layer doped with a conductive dopant may be formed at one side or a side and/or the other side or another side of the active layer AL. For example, the clad layer may include one or more of AlGaN and InAlGaN. However, the disclosure is not necessarily limited to the example described above.

The second semiconductor layer SCL2 may include a second conductive semiconductor. The second semiconductor layer SCL2 is disposed on the active layer AL, and may include a semiconductor layer of a type different from that of the first semiconductor layer SCL1. For example, the second semiconductor layer SCL2 may include an N-type semiconductor layer. For example, the second semiconductor layer SCL2 may include one or more of InAlGaN, GaN, AlGaN, InGaN, AIN, and InN, and may include an N-type semiconductor layer doped with a second conductive dopant such as Si, Ge, and Sn. However, the disclosure is not limited to the above-described examples. The second semiconductor layer SCL2 may include various materials.

In case that a voltage equal to or higher than a threshold voltage is applied to the first end portion EP1 and the second end portion EP2 of the light emitting element LD, electron-hole pairs in the active layer AL may combine with each other, and the light emitting element LD may emit light. By controlling the light emission of the light emitting element LD by using this principle, the light emitting element LD may be used as a light source in various devices.

The insulating film INF may be disposed on one surface or a surface of the light emitting element LD. The insulating film INF may surround an outer surface of the active layer AL, and may further surround a portion of each of the first semiconductor layer SCL1 and the second semiconductor layer SCL2. The insulating film INF may have a single-layered structure or a multi-layered structure.

The insulating film INF may expose the first and second end portions EP1 and EP2 of the light emitting element LD having different polarities. For example, the insulating film INF may expose one end or an end of each of the electrode layer ELL and the second semiconductor layer SCL2 adjacent to the first and second end portions EP1 and EP2 of the light emitting element LD. The insulating film INF may secure electrical stability of the light emitting element LD. The insulating film INF may improve life-span and efficiency by minimizing surface defects of the light emitting element LD. In case that light emitting elements LD are disposed to be close to each other, the insulating film INF may prevent a short circuit defect between the light emitting elements LD.

According to an embodiment, the insulating film INF may include one or more of a silicon oxide (SiOₓ), a silicon nitride (SiNₓ), a silicon oxynitride (SiOₓN_{y}), an aluminum oxide (AlOₓ), and a titanium oxide (TiOₓ). However, the disclosure is not necessarily limited to the example described above.

The electrode layer ELL may be disposed on the first semiconductor layer SCL1. The electrode layer ELL may be adjacent to the first end portion EP1. The electrode layer ELL may be electrically connected to the first semiconductor layer SCL1. A portion of the electrode layer ELL may be exposed. For example, the insulating film INF may expose one surface or a surface of the electrode layer ELL. The electrode layer ELL may be exposed in an area corresponding to the first end portion EP1. According to an embodiment, a lateral surface of the electrode layer ELL may be exposed. For example, the insulating film INF may cover a lateral surface of each of the first semiconductor layer SCL1, the active layer AL, and the second semiconductor layer SCL2, while may not cover at least a portion of a lateral surface of the electrode layer ELL. An electrical connection to another component of the electrode layer ELL adjacent to the first end portion EP1 may be readily made. According to an embodiment, the insulating layer INF may expose a portion of the lateral surface of the first semiconductor layer SCL 1 and/or the second semiconductor layer SCL2 as well as the lateral surface of the electrode layer ELL.

According to an embodiment, the electrode layer ELL may be an ohmic contact electrode. However, the disclosure is not necessarily limited to the example described above. For example, the electrode layer ELL may be a Schottky contact electrode.

According an embodiment, the electrode layer ELL may include one or more of chromium (Cr), titanium (Ti), aluminum (Al), gold (Au), nickel (Ni), and an oxide thereof and an alloy thereof. However, the disclosure is not necessarily limited to the example described above. According an embodiment, the electrode layer ELL may be substantially transparent. For example, the electrode layer ELL may include an indium tin oxide (ITO). Accordingly, the electrode layer ELL may transmit emitted light.

The structure and shape of the light emitting element LD are not limited to the above-described example, and the light emitting element LD may have various structures and shapes according to embodiments. For example, the light emitting element LD may further include an additional electrode layer that is disposed on one surface or a surface of the second semiconductor layer SCL2 and is adjacent to the second end portion EP2.

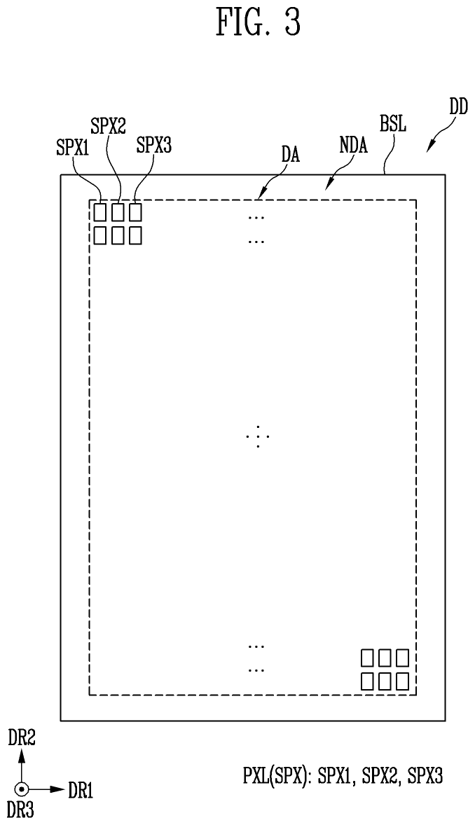

FIG. 3 illustrates a schematic top plan view of a display device according to an embodiment.

Referring to FIG. 3, a display device DD may include a base layer BSL, and a pixel PXL disposed on the base layer BSL. Although not shown in the drawing, the display device DD may further include a driving circuit part (for example, a scan driver and a data driver) for driving the pixel PXL, wires, and pads.

The display device DD (or the base layer BSL) may include a display area DA and a non-display area NDA. The non-display area NDA may mean an area other than the display area DA. The non-display area NDA may surround at least a portion of the display area DA.

The base layer BSL may form a base surface of the display device DD. The base layer BSL may be a rigid or flexible substrate or film. For example, the base layer BSL may be a hard substrate made of glass or tempered glass, a flexible substrate (or a thin film) made of a plastic or metallic material, or at least one layered insulating layer. The material and/or physical properties of the base layer BSL are not particularly limited. In an embodiment, the base layer BSL may be substantially transparent. Here, the “substantially transparent” may mean that light may be transmitted at one transmittance or more. In an embodiment, the base layer BSL may be translucent or opaque. The base layer BSL may include a reflective material according to an embodiment.

The display area DA may mean an area in which the pixel PXL is disposed. The non-display area NDA may mean an area in which the pixel PXL is not disposed. In the non-display area NDA, the driving circuit part, wires, and pads connected to the pixel PXL of the display area DA may be disposed.

According to an embodiment, the pixel PXL (or sub-pixel SPX) may be arranged or disposed according to a stripe or pentile (PENTILE™) arrangement structure, but the disclosure is not limited thereto, and various examples may be applied to the disclosure.

According to an embodiment, the pixel PXL (or sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one of the first sub-pixel SPX1, the second sub-pixel SPX2, and the third sub-pixel SPX3 may form one pixel unit capable of emitting light of various colors.

For example, each of the first sub-pixel SPX1, the second sub-pixel SPX2, and the third sub-pixel SPX3 may emit light of one color. For example, the first sub-pixel SPX1 may be a red pixel emitting red (for example, first color) light, and the second sub-pixel SPX2 may be a green pixel emitting green (for example, second color) light, and the third sub-pixel SPX3 may be a blue pixel emitting blue (for example, third color) light. According to an embodiment, the number of the second sub-pixels SPX2 may be greater than the number of the first sub-pixels SPX1 and the number of the third sub-pixels SPX3. However, the color, type, and/or number of the first sub-pixel SPX1, the second sub-pixel SPX2, and the third sub-pixel SPX3 forming each pixel unit described above are not limited to a specific example.

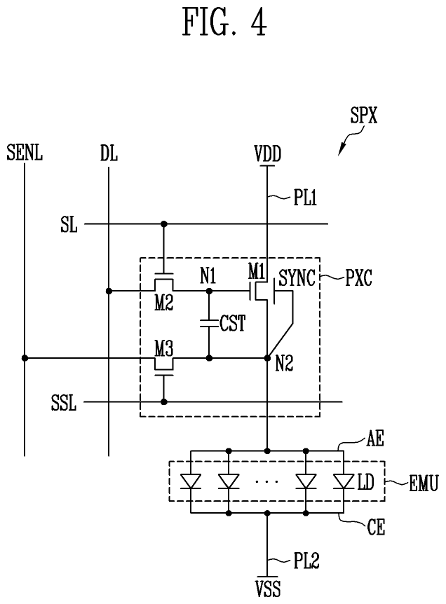

FIG. 4 illustrates a pixel circuit included in a sub-pixel according to an embodiment. Referring to FIG. 4, the sub-pixel SPX may include a pixel circuit PXC. The pixel circuit PXC may drive a light emitting unit EMU (or the light emitting elements LD). Each of the sub-pixels SPX for forming one pixel unit may include the pixel circuit PXC.

The pixel circuit PXC may be electrically connected to a scan line SL, a data line DL, a first power line PL1, and a second power line PL2. The pixel circuit PXC may be further electrically connected to a scan control line SSL and a sensing line SENL.

The sub-pixel SPX may include the light emitting unit EMU (or the light emitting elements LD) that emits light corresponding to a data signal provided from the data line DL.

The pixel circuit PXC may be disposed between the first power line PL1 and the light emitting unit EMU. The pixel circuit PXC may be electrically connected to the scan line SL to which a first scan signal is supplied and the data line DL to which a data signal is supplied. The pixel circuit PXC may be electrically connected to a scan control line SSL to which a second scan signal is supplied, and may be electrically connected to a sensing line SENL connected to a reference power (or an initialization power) or a sensing circuit. According to an embodiment, the second scan signal may be the same as or different from the first scan signal. In case that the second scan signal is the same as the first scan signal, the scan control line SSL may be integral with the scan line SL.

The pixel circuit PXC may include one or more circuit elements. For example, the pixel circuit PXC may include a first transistor M1, a second transistor M2, a third transistor M3, and a storage capacitor CST.

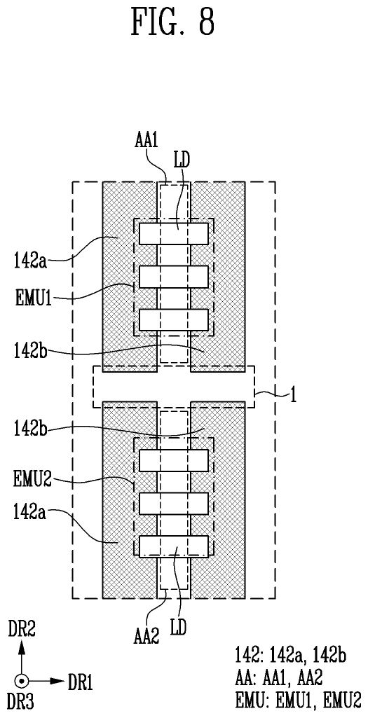

The first transistor MI may be electrically connected between the first power line PL1 and a second node N2. The second node N2 may be a node at which the pixel circuit PXC and the light emitting unit EMU are connected. For example, the second node N2 may be a node to which a first transistor electrode TEI (see FIG. 8) of the first transistor M1 and an anode connecting electrode AE of the light emitting unit EMU are connected. A gate electrode GE of the first transistor M1 (see FIG. 8) may be electrically connected to a first node N1. The first transistor M1 may control a driving current supplied to the light emitting unit EMU in response to a voltage of the first node N1. The first transistor M1 may be a driving transistor.

According to an embodiment, a sink conductive layer SYNC may be disposed under or below the first transistor M1. In case that the sub-pixel SPX is driven, a back-biasing technology (or a sync technology) in which a back-biasing voltage is applied to the sink conductive layer SYNC to move a threshold voltage of the first transistor MI in a negative or positive direction may be applied.

The second transistor M2 may be electrically connected between the data line DL and the first node N1. A gate electrode of the second transistor M2 may be electrically connected to the scan line SL. In case that a first scan signal of a gate-on voltage (for example, a high level voltage) is supplied from the scan line SL, the second transistor M2 may be turned on to electrically connect the data line DL and the first node N1.

For each frame period, a data signal of the corresponding frame is supplied to the data line DL, and the data signal is transmitted to the first node NI through the second transistor M2 during a period in which the first scan signal of the gate-on voltage is supplied. The second transistor M2 may be a switching transistor for transmitting each data signal to the inside of the sub-pixel SPX.

One electrode (for example, an upper electrode UE (see FIG. 8)) of the storage capacitor CST is electrically connected to the first node N1, and the other electrode (for example, a lower electrode LE (see FIG. 8)) thereof may be electrically connected to the second node N2. The storage capacitor CST is charged with a voltage corresponding to the data signal supplied to the first node N1 during each frame period.

The third transistor M3 may be electrically connected between the second node N2 and the sensing line SENL. A gate electrode of the third transistor M3 may be connected to the scan control line SSL (or the scan line SL). The third transistor M3 may be turned on in case that the second scan signal (or first scan signal) of a gate-on voltage (for example, a high level voltage) is supplied from the scan control line SSL to transmit the reference voltage (or initialization voltage) supplied to the sensing line SENL to the second node N2 or to transmit the voltage of the second node N2 to the sensing line SENL. The voltage of the second node N2 transmitted to the sensing circuit through the sensing line SENL may be supplied to an external circuit to be used to compensate for characteristic deviation of the sub-pixels SPX.

In FIG. 4, all of the transistors included in the pixel circuit PXC are illustrated as N-type transistors, but the disclosure is not limited thereto. For example, at least one of the first, second, and third transistors M1, M2, and M3 may be changed to a P-type transistor. The structure and driving method of the sub-pixel SPX may be variously changed according embodiments.

The light emitting unit EMU may include an anode connecting electrode AE, a cathode connecting electrode CE, and at least one light emitting element LD that are electrically connected between the first power line PL1 and the second power line PL2. The light emitting unit EMU may be formed by one or more light emitting element LD. According to an embodiment, the light emitting unit EMU may include light emitting elements LD connected in parallel between the anode connecting electrode AE and the cathode connecting electrode CE.

The power of the first power line PL1 and the power of the second power line PL2 may have different potentials. For example, the first power line PL1 may be electrically connected to a high-potential pixel power VDD to receive a high-potential power, and the second power line PL2 may be electrically connected to a low-potential pixel power VSS to receive a low-potential power. A potential difference between the power of the first power line PL1 and the power of the second power line PL2 (for example, a potential difference between the high potential power VDD and the low potential power VSS) may be set to be equal to and greater than a threshold voltage of the light emitting elements LD.

The first power line PL1 may be electrically connected to the first transistor M1 and the anode connecting electrode AE. The second power line PL2 may be electrically connected to the cathode connecting electrode CE.

Each light emitting element LD may be connected in a forward direction between the first power line PL1 and the second power line PL2 to form each effective light source. These effective light sources may be collected to form the light emitting unit EMU of the sub-pixel SPX.

The light emitting elements LD may emit light with luminance corresponding to a driving current supplied through the pixel circuit PXC. During each frame period, the pixel circuit PXC may supply a driving current corresponding to the data signal to the light emitting unit EMU. The driving current supplied to the light emitting unit EMU may be divided to flow in the light emitting elements LD. Accordingly, while each light emitting element LD emits light with a luminance corresponding to the current flowing therein, the light emitting unit EMU may emit light with luminance corresponding to the driving current.

In FIG. 4, an embodiment in which the sub-pixel SPX may include the light emitting unit EMU having a parallel structure has been disclosed, the disclosure is not limited thereto. For example, the sub-pixel SPX may include the light emitting unit EMU having a serial structure or a serial/in-parallel structure. The pixel circuit PXC for the sub-pixel SPX according to an embodiment is not limited to the above-described example. According to an embodiment, the pixel circuit PXC may further include seven transistors and one storage capacitor.

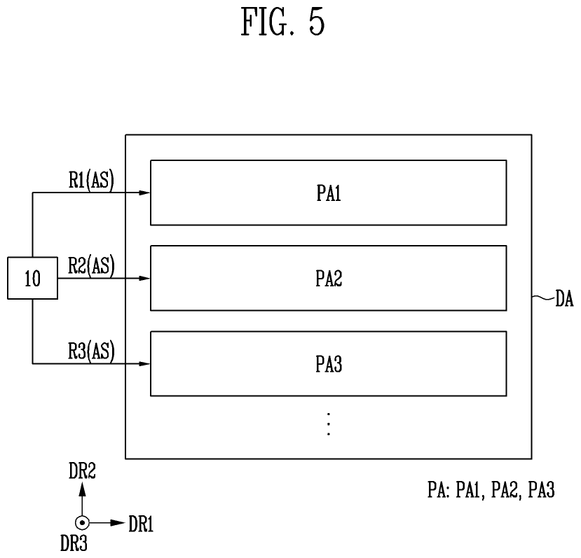

Hereinafter, a structure of a display device according to an embodiment will be described with reference to FIG. 5 to FIG. 13. Descriptions that may be redundant to those described above are simplified or are not repeated.

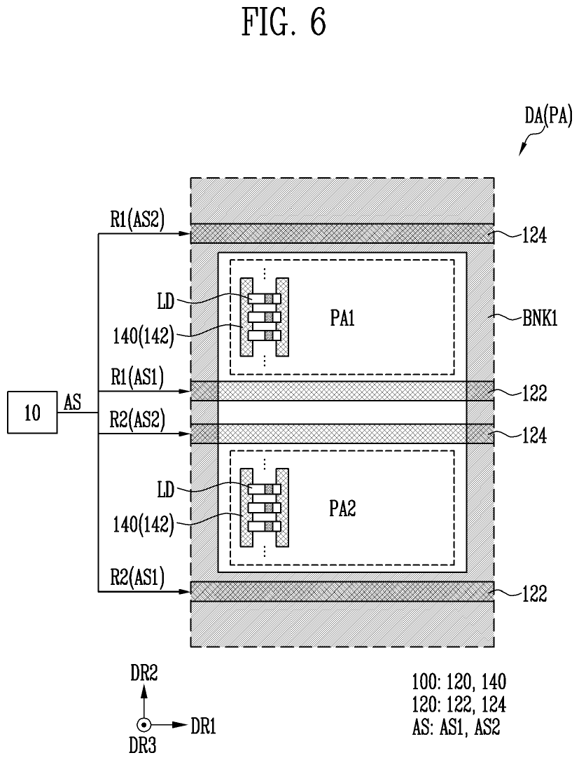

First, a structure in which alignment signals AS according to an embodiment are supplied will be described with reference to FIG. 5 and FIG. 6. FIG. 5 illustrates a schematic block diagram of a structure in which an alignment signal is supplied according to an embodiment. FIG. 6 illustrates a schematic top plan view of a display device according to an embodiment. FIG. 5 and FIG. 6 illustrate an embodiment in which the alignment signal AS is supplied to electrodes 100 in case that a process of aligning the light emitting elements LD is performed.

Referring to FIG. 5 and FIG. 6, alignment areas PA in which the light emitting elements LD are disposed may be formed in the display area DA. The alignment areas PA are defined as areas in which the light emitting elements LD are disposed (or aligned). According to an embodiment, the alignment areas PA may include a first alignment area PA1 disposed in a first row, a second alignment area PA2 disposed in a second row, and a third alignment area PA3 disposed in a third row. The number of the alignment areas PA is not particularly limited.

A shape of the alignment areas PA is not particularly limited, and may substantially have a shape extending in one direction or a direction. The alignment areas PA may include an area surrounded by a first bank BNK1.

The alignment areas PA may extend in a first direction DR1 within the display area DA. For example, the first alignment area PA1, the second alignment area PA2, and the third alignment area PA3 may extend in the first direction DR1. The extension of the alignment areas PA in the first direction DR1 may mean that a length of each alignment area PA along the first direction DR1 is greater than a length of each alignment area PA along a second direction DR2.

The alignment areas PA may be sequentially disposed along the second direction DR2 within the display area DA. The first alignment area PA1, the second alignment area PA2, and the third alignment area PA3 may be sequentially disposed along the second direction DR2.

An alignment device 10 may output the alignment signal AS, and may be electrically connected to components within the alignment areas PA. The alignment areas PA may be such that the alignment signals AS are supplied from separate wires.

For example, the alignment device 10 may supply the alignment signals AS to the electrodes 100 in the first alignment area PA1 through a first wire R1. The alignment device 10 may supply the alignment signals AS to the electrodes 100 in the second alignment area PA2 through a second wire R2. The alignment device 10 may supply the alignment signals AS to the electrodes 100 in the third alignment area PA3 through a third wire R3. According to an embodiment, the alignment device 10 may include a probe module capable of supplying an electrical signal to wires (for example, the first wire R1, the second wire R2, and the third wire R3). However, the disclosure is not limited thereto.

The alignment signal AS may be an electrical signal for aligning the light emitting elements LD. The alignment signal AS may include a first alignment signal AS1 and a second alignment signal AS2. The first alignment signal AS1 and the second alignment signal AS2 may have different waveforms, potentials, and/or phases. For example, the first alignment signal AS1 may be an AC signal, and the second alignment signal AS2 may be a ground signal. However, the disclosure is not limited to the example described above.

According to an embodiment, the first wire R1, the second wire R2, and the third wire R3 may form separate electrical paths. According to an embodiment, the first wire R1, the second wire R2, and the third wire R3 may be electrically separated from each other in areas other than the alignment device 10.

The electrodes 100 may be disposed in the display area DA to form a structure for aligning the light emitting elements LD. The electrodes 100 may include body electrodes 120 and branch electrodes 140.

The electrodes 100 may receive the alignment signals AS. For example, the body electrodes 120 may be electrically connected the wires (for example, the first to third wires R1, R2, and R3) that supply the alignment signals AS.

The body electrodes 120 may extend in the first direction DR1 within the display area DA. For example, the body electrodes 120 may extend in a same direction as the direction in which the alignment areas PA extend. The body electrodes 120 may extend in a direction different from the direction in which the alignment areas PA are spaced apart from each other. The body electrodes 120 may extend in the direction in which the light emitting elements LD extend. For example, the body electrodes 120 may extend in a direction from the first end portion EP1 toward the second end portion EP2 of the light emitting elements LD.

The body electrodes 120 may be adjacent to each other in the second direction DR2, but may be electrically separated from each other. Each of the body electrodes 120 may extend in the first direction DR1, and accordingly, the supplied alignment signals AS may be supplied to the inside of the alignment areas PA.

Adjacent electrodes 142 of the body electrodes 120 and the branch electrodes 140 may extend in different directions. For example, the adjacent electrodes 142 may extend in the second direction DR2, and the body electrodes 120 may extend in the first direction DR1 as described above.

The body electrodes 120 respectively disposed in the different alignment areas PA may be separated from each other. For example, the body electrodes 120 in the first alignment area PA1 and the body electrodes 120 in the second alignment area PA2 may be electrically separated from each other within the display area DA.

The body electrodes 120 may include a body electrode structure to receive different electrical signals. For example, the body electrodes 120 may include first body electrodes 122 and second body electrodes 124.

The first body electrodes 122 may be electrically connected to the alignment device 10, and may receive the first alignment signal AS1. The second body electrodes 124 may be electrically connected to the alignment device 10, and may receive the second alignment signal AS2.

Each of the first body electrode 122 and the second body electrode 124 may form one or more pairs.

For example, one or more pairs of the first body electrode 122 and the second body electrode 124 may correspond to the first alignment area PA1. For example, the first body electrode 122 may be disposed at one side or a side of the first alignment area PA1, and the second body electrode 124 may be disposed at the other side of the first alignment area PA1.

For example, one or more pairs of the first body electrode 122 and the second body electrode 124 may correspond to the second alignment area PA2. For example, the first body electrode 122 may be disposed at one side or a side of the second alignment area PA2, and the second body electrode 124 may be disposed at the other side of the second alignment area PA2.

The branch electrode 140 may be disposed between the body electrodes 120. For example, the branch electrode 140 may be disposed between the corresponding first body electrode 122 and the corresponding second body electrode 124. For example, the adjacent electrodes 142 of the branch electrodes 140 may be disposed between the corresponding first body electrode 122 and the corresponding second body electrode 124.

The branch electrode 140 may include adjacent electrodes 142 adjacent to the light emitting elements LD, and may include connecting branch electrodes 144 that may electrically connect the adjacent electrodes 142 and the body electrodes 120. This will be described in detail later.

The light emitting elements LD may be disposed between the corresponding first body electrode 122 and the corresponding second body electrode 124. The light emitting elements LD may be disposed between the adjacent electrodes 142 in the alignment areas PA. For example, the light emitting elements LD may be disposed on a pair of adjacent electrodes 142 extending in the second direction DR2.

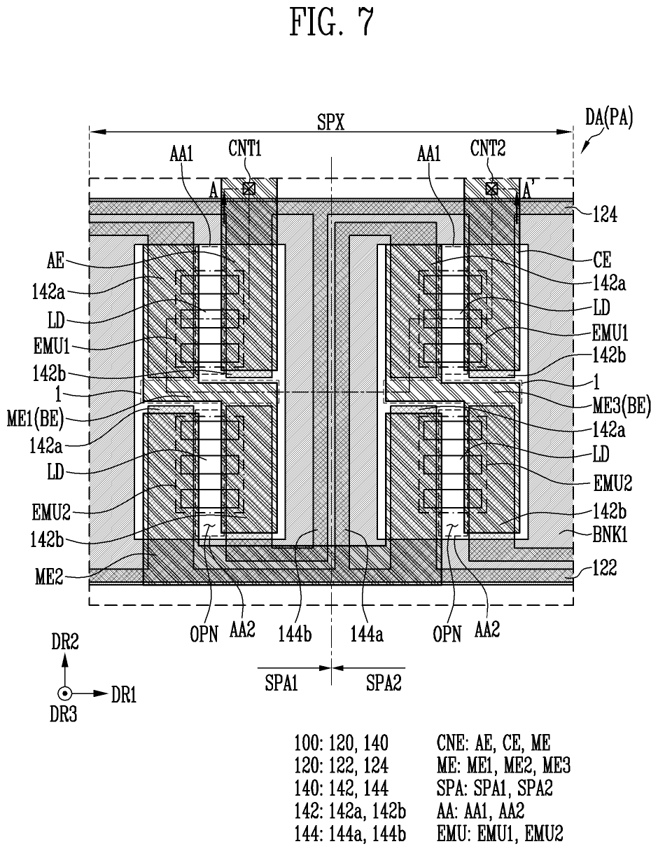

Hereinafter, a planar structure and a cross-sectional structure of a display device according to an embodiment will be described with reference to FIG. 7 to FIG. 9. Descriptions that may be redundant to those described above are simplified or are not repeated.

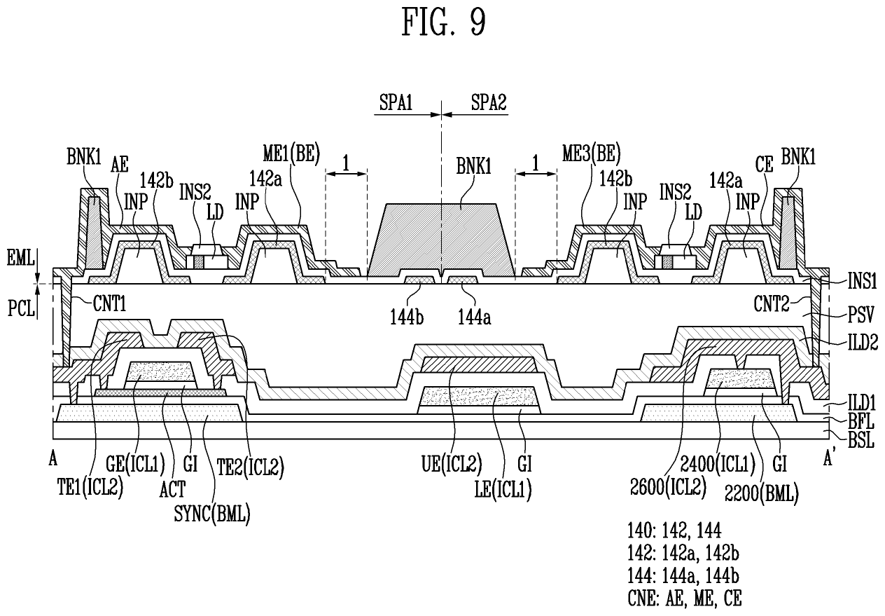

FIG. 7 illustrates a schematic top plan view of a display device according to an embodiment. FIG. 8 illustrates a schematic top plan view of a structure including an open area according to an embodiment. FIG. 9 illustrates a schematic cross-sectional view taken along line A-A′ of FIG. 7.

Referring to FIG. 7 and FIG. 8, the alignment areas PA are disposed may be formed in the display area DA. The display area DA may include the alignment areas DA. According to an embodiment, the alignment area PA may include sub-alignment areas SPA, and in an embodiment, a structure in which two or more sub-alignment areas SPA form one sub-pixel SPX is shown.

For example, in an embodiment, the first sub-alignment area SPA1 and the second sub-alignment area SPA2 may correspond to the same one sub-pixel SPX. For example, the first sub-alignment area SPA1 and the second sub-alignment area SPA2 may overlap a sub-pixel area SPXA of one sub-pixel SPX.

The sub-pixel SPX may contain two or more sub-alignment areas SPA. The sub-alignment areas SPA may include a first sub-alignment area SPA1 and a second sub-alignment area SPA2. FIG. 7 illustrates an embodiment in which two sub-alignment areas SPA form the sub-pixel SPX, but the disclosure is not limited thereto, and the number of the sub-alignment areas SPA may be variously changed.

The light emitting elements LD may be disposed in each of the sub-alignment areas SPA, and a light emitting area may be formed therein. The sub-alignment areas SPA may overlap an opening OPN defined by the first bank BNK1.

According to an embodiment, the first bank BNK1 may be disposed in the periphery of the sub-alignment area SPA. The first bank BNK1 may surround at least a portion of the sub-alignment area SPA. The first bank BNK1 may surround at least some of the pathway areas AA.

According to an embodiment, the first bank BNK1 may protrude in a thickness direction (for example, a third direction DR3) of the base layer BSL (see FIG. 9), and may surround the light emitting area in which the light emitting elements LD are disposed. According to an embodiment, an ink including the light emitting element LD is supplied to the opening OPN defined by the first bank BNK1, so that the light emitting element LD may be disposed in the opening OPN.

According to an embodiment, the first bank BNK1 may include an organic material such as an acrylates resin, an epoxy resin, a phenolic resin, a polyamides resin, a polyimide resin, a polyesters resin, a polyphenylenesulfides resin, or a benzocyclobutene (BCB). However, the disclosure is not limited to the example described above.

At least some of the electrodes 100 may extend in the first direction DR1, and at least some other of the electrodes 100 may extend in the second direction DR2, and thus, the electrodes 100 may form a mesh structure. For example, referring to FIG. 5 and FIG. 6, the body electrodes 120 may each extend in the first direction DR1, so the electrodes 100 substantially extend in the first direction DR1, and may form two or more mesh structures spaced apart from each other in the second direction DR2.

The first body electrode 122 may be disposed at one side or a side (for example, a lower portion) of the sub-alignment areas SPA. The first body electrode 122 may be entirely disposed in the sub-alignment areas SPA. For example, the first body electrode 122 may overlap the first sub-alignment area SPA1 along the second direction DR2, and may also overlap the second sub-alignment area SPA2.

The second body electrode 124 may be disposed at the other side (for example, a lower portion) of the sub-alignment areas SPA. The second body electrode 124 may be entirely disposed in the sub-alignment areas SPA. For example, the second body electrode 124 may overlap the first sub-alignment area SPA1 along the second direction DR2, and may also overlap the second sub-alignment area SPA2.

The branch electrodes 140 may be electrically connected to the body electrodes 120. The branch electrodes 140 may include the adjacent electrodes 142 and the connecting branch electrodes 144. The connecting branch electrodes 144 may include a first connecting branch electrode 144a and a second connecting branch electrode 144b.

The adjacent electrodes 142 may be disposed in each of the sub-alignment areas SPA. The adjacent electrodes 142 may be electrically connected to the body electrodes 120. For example, some of the adjacent electrodes 142 may be directly electrically connected to the body electrodes 120. Some of the adjacent electrodes 142 may be electrically connected to the body electrodes 120 through the connecting branch electrodes 144.

According to an embodiment, a first adjacent electrode 142a on one side or a side (for example, a lower side, a second pathway area AA2) of the alignment area PA may be electrically connected to the first body electrode 122. For example, the first adjacent electrode 142a on one side or a side of the second sub-alignment area SPA2 may be connected to the first body electrode 122. The first adjacent electrode 142a on one side or a side of the first sub-alignment area SPA1 may be electrically connected to the first body electrode 122.

According to an embodiment, the first adjacent electrode 142a on the other side (for example, the upper side, the first pathway area AA1) of the alignment area PA may be electrically connected to the first body electrode 122 through a first connecting branch electrode 144a. For example, at least a portion of the first adjacent electrode 142a on the other side of the second sub-alignment area SPA2 may be electrically connected to the first body electrode 122 through the first connecting branch electrode 144a extending in the second direction DR2. The first adjacent electrode 142a on the other side of the first sub-alignment area SPA1 may be electrically connected to the first body electrode 122 through the first connecting branch electrode 144a.

According to an embodiment, a second adjacent electrode 142b on one side or a side (for example, the lower side, the second pathway area AA2) of the alignment area PA may be electrically connected to the second body electrode 124 through a second connecting branch electrode 144b. For example, at least a portion of the second adjacent electrode 142b on one side or a side of the second sub-alignment area SPA2 may be electrically connected to the second body electrode 124 through the second connecting branch electrode 144b extending in the second direction DR2. The second adjacent electrode 142b on one side or a side of the first sub-alignment area SPA1 may be electrically connected to the second body electrode 124 through the second connecting branch electrode 144b.

According to an embodiment, the second adjacent electrode 142b on the other side (for example, the upper side, the first pathway area AA1) of the alignment area PA may be electrically connected to the second body electrode 124. For example, the second adjacent electrode 142b on the other side of the second sub-alignment area SPA2 may be connected to the second body electrode 124. The second adjacent electrode 142b on the other side of the first sub-alignment area SPA1 may be electrically connected to the second body electrode 124.

The adjacent electrodes 142 may form an electric field for aligning the light emitting elements LD. The adjacent electrodes 142 may form a pair, and the formed pair may be spaced apart in the first direction DR1. The adjacent electrodes 142 may extend in the second direction DR2.

For example, the adjacent electrodes 142 may include the first adjacent electrode 142a and the second adjacent electrode 142b. The first adjacent electrode 142a may be an alignment electrode to which the first alignment signal AS1 may be supplied. The second adjacent electrode 142b may be an alignment electrode to which the second alignment signal AS2 may be supplied. The first adjacent electrode 142a and the second adjacent electrode 142b may form a pair, and the light emitting elements LD may be aligned between the first adjacent electrode 142a and the second adjacent electrode 142b.

According to an embodiment, an ink including the light emitting element LD may be supplied (or provided) to the opening OPN, the first alignment signal AS1 may be supplied to the first adjacent electrode 142a, and the second alignment signal AS2 may be supplied to the second adjacent electrode 142b. An electric field is formed between (or on) the first adjacent electrode 142a and the second adjacent electrode 142b, so that the light emitting elements LD may be aligned between the first adjacent electrode 142a and the second adjacent electrode 142b based on the electric field. For example, the light emitting elements LD may be moved (or rotated) by force (for example, dielectrophoresis (DEP) force) according to the electric field to be aligned (or disposed) on the first adjacent electrode 142a and the second adjacent electrode 142b.

The connecting branch electrodes 144 may be disposed between the adjacent sub-alignment areas SPA in the first direction DR1. The connecting branch electrodes 144 may be disposed between the first body electrode 122 and the second body electrode 124. The connecting branch electrodes 144 may overlap the first bank BNK1 in a plan view. The connecting branch electrodes 144 may electrically connect the adjacent electrodes 142 adjacent to each other in the first direction DR1. Accordingly, two or more pathway areas AA in which the light emitting elements LD may be aligned may be formed in each of the sub-alignment areas SPA.

The pathway area AA may be an area in which the adjacent electrodes 142 may be spaced apart from each other so that the light emitting elements LD may be aligned based on the electric field. The pathway area AA may be defined by a number corresponding to a pair of the adjacent electrodes 142 spaced apart from each other.

The pathway area AA may be disposed within the alignment area PA. The pathway areas AA may be defined in each of the sub-alignment areas PA. The pathway area AA may be defined at various positions within the alignment area PA.

The pathway area AA may include the first pathway area AAl and the second pathway area AA2. The first pathway area AA1 and the second pathway area AA2 may be spaced apart from each other along the second direction DR2. For example, the first pathway area AA1 and the second pathway area AA2 may be spaced apart from each other in a direction different from the direction in which the body electrodes 120 extend.

According to an embodiment, the adjacent electrodes 142 of the first pathway area AA1 and the adjacent electrodes 142 of the second pathway area AA2 may be spaced apart from each other with an open area 1 interposed therebetween. The open area 1 may not overlap the first bank BNK1 in a plan view.

For example, the first adjacent electrode 142a of the first pathway area AA1 and the first adjacent electrode 142a of the second pathway area AA2 may be physically spaced apart from each other. The second adjacent electrode 142b of the first pathway area AA1 and the second adjacent electrode 142b of the second pathway area AA2 may be physically spaced apart from each other.

According to an embodiment, in the state in which the open area 1 is formed, the light emitting elements LD may be included in an ink to be supplied to the opening OPN. Since a structure in which the adjacent electrodes 142 form pairs is not formed in the open area 1, a risk in which the light emitting elements LD are disposed in the open area 1 may be reduced.

According to an embodiment, the open area 1 may overlap an intermediate electrode ME (for example, a bridge electrode BE) in a plan view.

According to an embodiment, in the sub-alignment area SPA, two or more pathway areas AA may be formed, and two or more light emitting units EMU may be electrically connected in series. For example, the light emitting elements LD in the first pathway area AA1 may form a first light emitting unit EMU1, the light emitting elements LD in the second pathway area AA2 may form a second light emitting unit EMU2, and the first light emitting unit EMU1 and the second light emitting unit EMU2 may be electrically connected to each other.

The light emitting element LD disposed in the first pathway area AA1 to form the first light emitting unit EMU1 may be referred to as a first light emitting element. The light emitting element LD disposed in the second pathway area AA2 to form the second light emitting unit EMU2 may be referred to as a second light emitting element.

According to an embodiment, respective light emitting units EMU of two or more adjacent sub-alignment areas SPA may be electrically connected to each other. For example, respective light emitting units EMU of the sub-alignment areas SPA may be electrically connected through connecting electrodes CNE including the intermediate connecting electrode ME, the anode connecting electrode AE, and the cathode connecting electrode CE.

Between the anode connecting electrode AE and the cathode connecting electrode CE, the light emitting units EMU may be electrically connected through the intermediate connecting electrode ME functioning as the bridge electrode BE.

For example, the anode connecting electrode AE, the first light emitting unit EMU1 of the first sub-alignment area SPA1, a first intermediate connecting electrode ME1, the second light emitting unit EMU2 of the first sub-alignment area SPA1, a second intermediate connecting electrode ME2, the first light emitting unit EMU1 of the second sub-alignment area SPA2, a third intermediate connecting electrode ME3, and the second light emitting unit EMU2 of the second sub-alignment area SPA2, and the cathode connecting electrodes CE may be sequentially electrically connected.

According to an embodiment, the first intermediate connecting electrode ME1 may overlap the open area 1 in the first sub-alignment area SPA1 in a plan view. The third intermediate connecting electrode ME3 may overlap open area 1 in the second sub-alignment area SPA2 in a plan view. At least a portion of the second intermediate connecting electrode ME2 may be bent, a portion of the second intermediate connecting electrode ME2 may be disposed in the first sub-alignment area SPA1, and another portion of the second intermediate connecting electrode ME2 may be disposed in the second sub-alignment area SPA2.

According to an embodiment, the anode connecting electrode AE and the cathode connecting electrode CE may be electrically connected through wires of the pixel circuit layer PCL and contact parts CNT1 and CNT2 without passing through the electrodes 100. For example, the anode connecting electrode AE may be electrically connected to a driving transistor (for example, the first transistor M1) formed on the pixel circuit layer PCL through the first contact part CNT1. The anode connecting electrode AE may be electrically connected to the first power line PL1 formed on the pixel circuit layer PCL. The cathode connecting electrode CE may be electrically connected to the second power line PL2 through the second contact portion CNT2 formed on the pixel circuit layer PCL.

According to an embodiment, a structure in which the light emitting units EMU in which the light emitting elements LD are formed in an in parallel structure are electrically connected to each other in series may be provided. According to the structure of an embodiment, the light emitting structure may be precisely controlled, and even in case that one of the light emitting elements LD is abnormally arranged or disposed, light emission may be normally performed.

As described above, the disposition of the light emitting elements LD in the open area 1, which is a position corresponding to the bridge electrode BE, may be minimized. For example, the open area 1 may not overlap the light emitting element LD in a plan view. Since the light emitting elements LD supplied to the open area 1 may be difficult to normally emit light, there is a need to minimize the number of the light emitting elements LD supplied to the open area 1.

According to an embodiment, the open area 1 may be defined to minimize the supply of the light emitting elements LD to an unnecessary partial area, and the light emitting elements LD may be selectively aligned in an essential partial area. Accordingly, the process cost may be substantially reduced and the process efficiency is increased.

The cross-sectional structure of the display device DD according to an embodiment will be described with reference to FIG. 8.

Referring to FIG. 8, the display device DD may include a pixel circuit layer PCL and a light emitting element layer EML.

The pixel circuit layer PCL may include a base layer BSL. As described above, the base layer BSL may form a base of the display device DD.

The pixel circuit layer PCL may include wires and insulating layers forming the pixel circuit PXC. For example, the pixel circuit layer PCL may include a lower auxiliary electrode layer BML, a buffer layer BFL, an active layer ACT, a gate insulating layer GI, a first interlayer conductive layer ICL1, a first interlayer insulating layer ILD1, a second interlayer conductive layer ICL2, a second interlayer insulating layer ILD2, and a passivation layer PSV.

The lower auxiliary electrode layer BML may include a sink conductive layer SYNC and a first conductive layer 2200.

The sink conductive layer SYNC may overlap the active layer ACT and the gate electrode GE in a plan view. The sink conductive layer SYNC may be electrically connected to the first transistor electrode TE1. For example, a source signal of the first transistor M1 may be applied to the sink conductive layer SYNC.

The first conductive layer 2200 may form a portion of the second power line PL2. The first conductive layer 2200 may be electrically connected to a third conductive layer 2600 through one contact member.

The lower auxiliary electrode layer BML may include one or more of gold (Au), silver (Ag), aluminum (Al), molybdenum (Mo), chromium (Cr), titanium (Ti), nickel (Ni), neodymium (Nd), copper (Cu), and platinum (Pt). However, the disclosure is not necessarily limited to the example described above.

The buffer layer BFL may be disposed on the lower auxiliary electrode layer BML and the base layer BSL. The buffer layer BFL may cover the lower auxiliary electrode layer BML.

The buffer layer BFL may prevent diffusion of impurities or moisture permeation into the active layer ACT. According to an embodiment, the buffer layer BFL may include one or more of a silicon nitride (SiNₓ), a silicon oxide (SiOₓ), a silicon oxynitride (SiOₓN_{y}), and an aluminum oxide (AlOₓ). However, the disclosure is not necessarily limited to the example described above.

The active layer ACT may be disposed on the buffer layer BFL. The active layer ACT may form a portion of the active portion of the first transistor M1. The active layer ACT may include a semiconductor. For example, the active layer ACT may include one or more of a polysilicon, a low temperature polycrystalline silicon (LTPS), an amorphous silicon, and an oxide semiconductor. The active layer ACT may form the channel of the first transistor M1. At least a portion of the active layer ACT may be doped with impurities.

The gate insulating layer GI may be disposed on the buffer layer BFL and the active layer ACT. The gate insulating layer GI may be disposed between the gate electrode GE of the first transistor M1 and the active layer ACT.

The gate insulating layer GI may include one or more of a silicon nitride (SiNₓ), a silicon oxide (SiOₓ), a silicon oxynitride (SiOₓN_{y}), and an aluminum oxide (AlOₓ). However, the disclosure is not limited thereto.

The first interlayer conductive layer ICL1 may be disposed on the gate insulating layer GI or the buffer layer BFL. The first interlayer conductive layer ICL1 may form the gate electrode GE of the first transistor M1, the lower electrode LE of the storage capacitor CST, and a second conductive layer 2400.

The first interlayer conductive layer ICL1 may include one or more of gold (Au), silver (Ag), aluminum (Al), molybdenum (Mo), chromium (Cr), titanium (Ti), nickel (Ni), neodymium (Nd), copper (Cu), and platinum (Pt). However, the disclosure is not necessarily limited to the example described above.

The gate electrode GE may be disposed to correspond to the position of the channel area of the active layer ACT of the first transistor M1.

The lower electrode LE of the storage capacitor CST may be disposed to face the upper electrode UE thereof.

The second conductive layer 2400 may form a portion of the second power line PL2. The second conductive layer 2400 may be electrically connected to the third conductive layer 2600 through one contact member.

The first interlayer insulating layer ILDI may be disposed on the first interlayer conductive layer ICL1. The first interlayer insulating layer ILDI may cover the first interlayer conductive layer ICL1.

The first interlayer insulating layer ILD1 may include one or more of a silicon nitride (SiNₓ), a silicon oxide (SiOₓ), a silicon oxynitride (SiOₓN_{y}), and an aluminum oxide (AlOₓ). However, the disclosure is not limited thereto.

The second interlayer conductive layer ICL2 may be disposed on the second interlayer insulating layer ILD1. The second interlayer conductive layer ICL2 may form the first and second transistor electrodes TE1 and TE2 of the first transistor M1, the upper electrode UE of the storage capacitor CST, and the third conductive layer 2600.

The second interlayer conductive layer ICL2 may include one or more of gold (Au), silver (Ag), aluminum (Al), molybdenum (Mo), chromium (Cr), titanium (Ti), nickel (Ni), neodymium (Nd), copper (Cu), and platinum (Pt). However, the disclosure is not necessarily limited to the example described above.

The first and second transistor electrodes TE1 and TE2 may form the source or drain electrode of the first transistor M1. For example, the first transistor electrode TE1 as a source electrode may be electrically connected to the sink conductive layer SYNC and may be electrically connected to the anode connecting electrode AE through the first contact part CNT1, and the second transistor electrode TE2 may be a drain electrode.

The upper electrode UE may form one electrode of the storage capacitor CST to form an opposite surface to the lower electrode LE.

The third conductive layer 2600 may form a portion of the second power line PL2. The third conductive layer 2600 may be electrically connected to the cathode connecting electrode CE through the second contact part CNT2.

The second interlayer insulating layer ILD2 may be disposed on the second interlayer conductive layer ICL2. The second interlayer insulating layer ILD2 may cover the second interlayer conductive layer ICL2.

The second interlayer insulating layer ILD2 may include one or more of a silicon nitride (SiNₓ), a silicon oxide (SiOₓ), a silicon oxynitride (SiOₓN_{y}), and an aluminum oxide (AlOₓ). However, the disclosure is not limited thereto.

The passivation layer PSV may be disposed on the second interlayer insulating layer ILD2. According to an embodiment, the passivation layer PSV may be a via layer. The passivation layer PSV may include an organic material. For example, the organic material may include one or more of an acrylic resin, an epoxy resin, a phenol resin, a polyamide resin, a polyimide rein, a polyester resin, a polyphenylenesulfide resin, and a benzocyclobutene (BCB). However, the disclosure is not necessarily limited to the example described above.

The light emitting element layer EML may be disposed on the pixel circuit layer PCL. The light emitting element layer EML may include insulating patterns INP, adjacent electrodes 142, connecting branch electrodes 144, a first insulating layer INS1, a first bank BNK1, light emitting elements LD, a second insulating layer INS2, and connecting electrodes CNE.

The insulating patterns INP may form one step so that the light emitting elements LD may be readily aligned in the pathway areas AA. According to an embodiment, the insulating patterns INP may be partition walls. According to an embodiment, the insulating patterns INP may include at least one organic material and/or inorganic material. However, the disclosure is not necessarily limited to a particular example.

The adjacent electrodes 142 may form the pathway areas AA. According to an embodiment, some of the adjacent electrodes 142 may be disposed on the insulating patterns INP to form a reflective wall.

The connecting branch electrodes 144 may be disposed on the passivation layer PSV to be covered by the first insulating layer INS1. The connecting branch electrodes 144 may be disposed to be adjacent to an area between the first sub-alignment area SPA1 and the second sub-alignment area SPA2.

According to an embodiment, the open area 1 may be formed in at least a partial area, and the light emitting element LD may not be disposed at a position corresponding to the open area 1.

The first insulating layer INS1 may be disposed on the adjacent electrodes 142 and the connecting branch electrodes 144. The first insulating layer INS1 may include one inorganic material, but is not particularly limited thereto.

The first bank BNK1 may be disposed on the first insulating layer INS1. As described above, the first bank BNK1 may form a space in which an ink including the light emitting element LD may be accommodated.

The light emitting element LD may be disposed on a first insulating layer INS1 in an area surrounded by the first bank BNK1. According an embodiment, the light emitting element LD may emit light based on an electrical signal (for example, an anode signal and a cathode signal) provided from the anode connecting electrode AE and the cathode connecting electrode CE.

The second insulating layer INS2 may be disposed on the light emitting element LD. The second insulating layer INS2 may cover the active layer AL of the light emitting element LD. The second insulating layer INS2 may expose at least a portion of the light emitting element LD. For example, the second insulating layer INS2 may not cover the first end portion EP1 and the second end portion EP2 of the light emitting element LD, and accordingly, the first end portion EP1 and the second end portion EP2 of the light emitting element LD may be exposed and may be electrically connected to some of the connecting electrodes CNE, respectively. According to an embodiment, another portion of the second insulating layer INS2 may be disposed on the first bank BNK1 and the first insulating layer INS1.

In case that the second insulating layer INS2 is formed on the light emitting elements LD after the alignment of the light emitting elements LD is completed, it is possible to prevent the light emitting elements LD from deviating from an aligned position.

The second insulating layer INS2 may have a single-layered or multi-layered structure. The second insulating layer INS2 may include one inorganic material, but is not particularly limited thereto.

The connecting electrodes CNE (for example, the anode connecting electrode AE, the cathode connecting electrode CE, and the intermediate connecting electrode ME) may be disposed on first insulating layer INS1 and second insulating layer INS2. Some of the connecting electrodes CNE may be electrically connected to the first end portion EP1 of the light emitting element LD. Some of the connecting electrodes CNE may be electrically connected to the second end portion EP2 of the light emitting element LD.

The anode connecting electrode AE may be electrically connected to the first transistor MI through the first contact part CNT1 penetrating the first insulating layer INS1, the passivation layer PSV, and the second interlayer insulating layer ILD2.

The cathode connecting electrode CE may be electrically connected to the second power line PL2 through the second contact part CNT2 penetrating the first insulating layer INS1, the passivation layer PSV, and the second interlayer insulating layer ILD2.

According to an embodiment, the connecting electrodes CNE may be patterned at the same time point in the same process. However, the disclosure is not necessarily limited to the example described above. After one of the connecting electrodes CNE is patterned, the other electrodes thereof may be patterned.

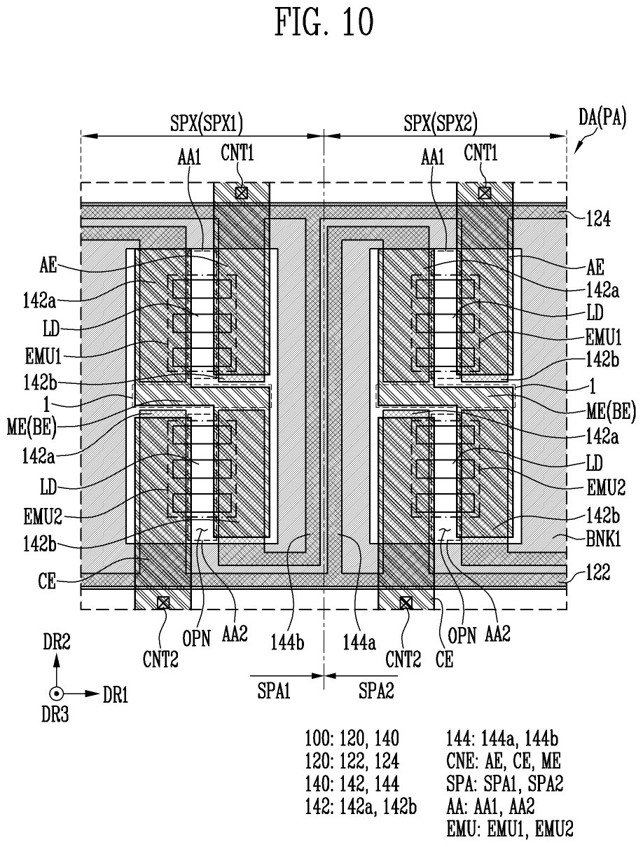

Hereinafter, a structure of a display device according to an embodiment will be described with reference to FIG. 10. FIG. 10 illustrates a schematic top plan view of a display device according to an embodiment. Descriptions that may be redundant to those described above are simplified or are not repeated.

An embodiment shown in FIG. 10 is different from an embodiment described above with reference to FIG. 7 to FIG. 9 in that each of the sub-alignment areas SPA forms a sub-pixel SPX.

For example, the light emitting elements LD (or the light emitting units EMU) of the first sub-alignment area SPA1 may correspond to the first sub-pixel SPX1 and form the first sub-pixel SPX1, the light emitting elements LD (or the light emitting units EMU) of the second sub-alignment area SPA2 may correspond to the second sub-pixel SPX2 and form the second sub-pixel SPX1, and for example, the first sub-alignment area SPA1 may overlap a first sub-pixel area SPXA1 of the first sub-pixel SPX1. The second sub-alignment area SPA2 may overlap a second sub-pixel area SPXA2 of the second sub-pixel SPX2.

The anode connecting electrode AE and the cathode connecting electrode CE may be formed corresponding to each of the sub-alignment areas SPA. According to an embodiment, the sub-pixels SPX of a finer scale may be defined.

In an embodiment, the open area 1 is also defined, so that alignment efficiency of the light emitting elements LD may be improved, and unnecessary process costs may be reduced.

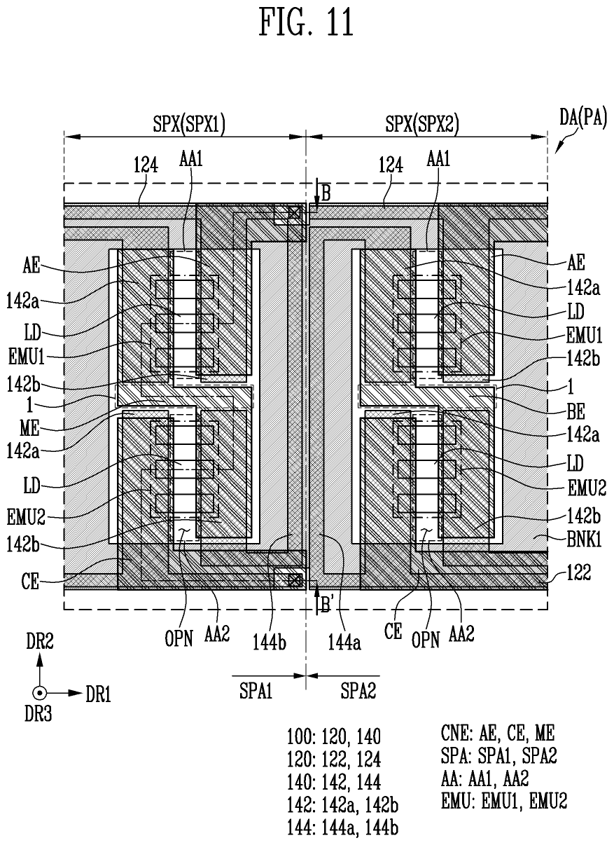

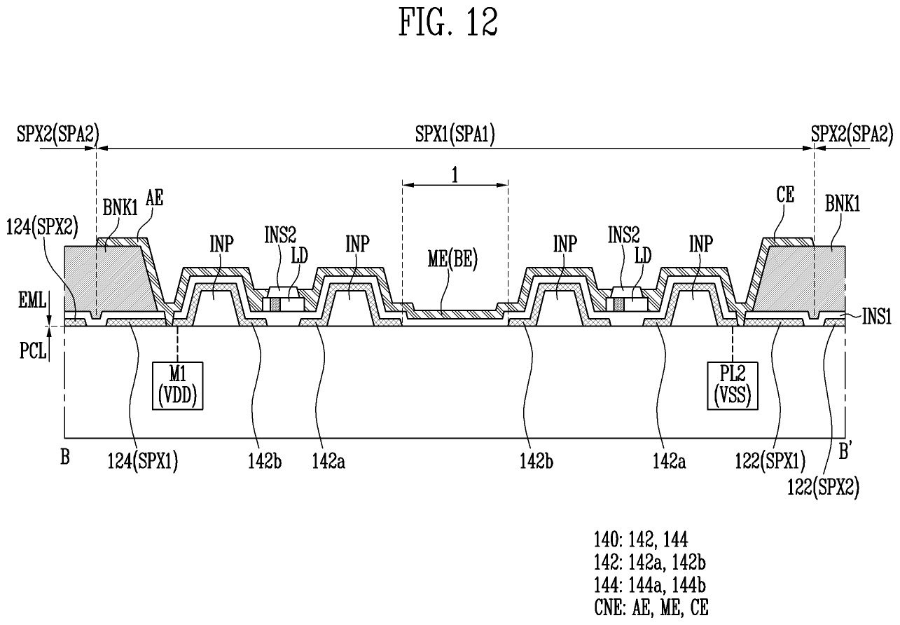

Hereinafter, a structure of a display device according to an embodiment will be described with reference to FIG. 11 and FIG. 12. FIG. 11 illustrates a schematic top plan view of a display device according to an embodiment. FIG. 12 illustrates a schematic cross-sectional view taken along line B-B′ of FIG. 11. Descriptions that may be redundant to those described above are simplified or are not repeated.

An embodiment shown in FIG. 11 and FIG. 12 is different from an embodiment described above with reference to FIG. 7 to FIG. 9 in that the anode connecting electrode AE and the cathode connecting electrode CE are electrically connected to wires of the pixel circuit layer PCL through the electrodes 100.

According to an embodiment, each of the sub-alignment areas SPA may form the sub-pixel SPX, and the anode connecting electrode AE and the cathode connecting electrode CE of each of the sub-alignment areas SPA may be electrically connected to some of the electrodes 100.

For example, the anode connecting electrode AE may be electrically connected to the first body electrode 122. The cathode connecting electrode CE may be electrically connected to the second body electrode 124. The first bank BNK1 may not be disposed in an area in which the anode connecting electrode AE and the first body electrode 122 are electrically connected to each other. The first bank BNK1 may not be disposed in an area in which the cathode connecting electrode CE and the second body electrode 124 are electrically connected to each other.

Accordingly, the anode connecting electrode AE may be electrically connected to the first transistor M1 through the first body electrode 122. The anode connecting electrode AE may receive the high-potential pixel power VDD through the first body electrode 122. The cathode connecting electrode CE may be electrically connected to the second power line PL2 through the second body electrode 124 to receive the low potential pixel power VSS.

In an embodiment, the open area 1 is also defined, so that alignment efficiency of the light emitting elements LD may be improved, and unnecessary process costs may be reduced.

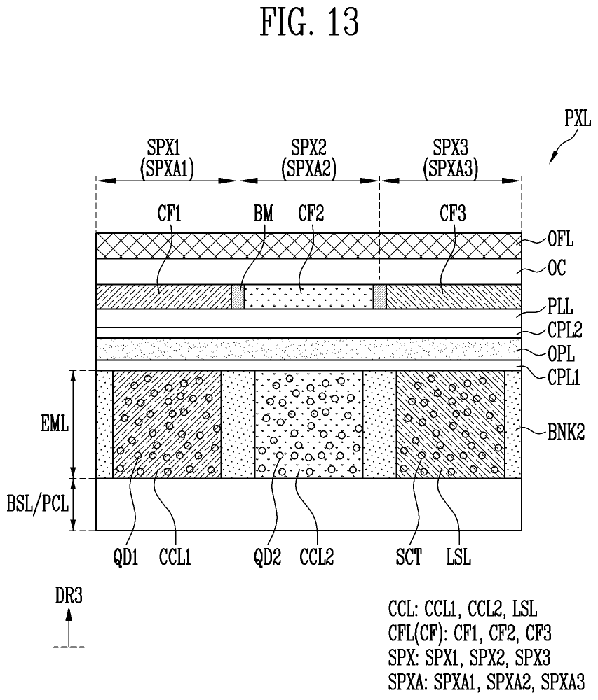

Hereinafter, a cross-sectional structure of a pixel PXL according to an embodiment will be described with reference to FIG. 13. FIG. 13 illustrates a schematic cross-sectional view of a pixel according to an embodiment.

FIG. 13 schematically illustrates a cross-sectional structure of the sub-pixels SPX, focusing on components disposed on the light emitting element layer EML.

Referring to FIG. 13, the sub-pixel areas SPXA respectively corresponding to the sub-pixels SPX may be formed in the display area DA. The sub-pixel areas SPXA may include a first sub-pixel area SPXA1 corresponding to the first sub-pixel SPX1, a second sub-pixel area SPXA2 corresponding to the second sub-pixel SPX2, and a third sub-pixel area SPXA3 corresponding to the third sub-pixel SPX3. The first sub-pixel area SPXA1, the second sub-pixel area SPXA2, and the third sub-pixel area SPXA3 may be arranged or disposed along the first direction DR1.

The second bank BNK2 is disposed between the first to third sub-pixel areas SPXA1, SPXA2, and SPXA3 or at a boundary therebetween, and may define a space (or an area) respectively overlapping the first to third sub-pixel areas SPXA1, SPXA2, and SPXA3. A space defined by the second bank BNK2 may be an area in which a color converting layer CCL may be provided.

The second bank BNK2 may be disposed to surround one area or an area in the light emitting element layer EML. The second bank BNK2 may protrude in the thickness direction (for example, the third direction DR3) of the base layer BSL to define one area or an area, and the space in which the color converting layer CCL is provided may be formed in the opening OPN.

The second bank BNK2 may include an organic material such as an acrylates resin, an epoxy resin, a phenol resin, a polyamides resin, a polyimide resin, a polyesters resin, a polyphenylenesulfides resin, or a benzocyclobutene. However, the disclosure is not limited thereto.

The color converting layer CCL may be disposed on the light emitting elements LD in the space surrounded by the second bank BNK2. The color converting layer CCL may include a first color converting layer CCL1 disposed on the first sub-pixel SPX1, a second color converting layer CCL2 disposed on the second sub-pixel SPX2, and a scattering layer LSL disposed on the third sub-pixel SPX3.

The color converting layer CCL may be disposed on the light emitting element LD. The color converting layer CCL may change a wavelength of light. According to an embodiment, the first to third sub-pixels SPX1, SPX2, and SPX3 may include the light emitting elements LD that emit light of a same color. For example, the first to third sub-pixels SPX1, SPX2, and SPX3 may include the light emitting elements LD that emit light of a third color (or blue color). The color converting layer CCL including color converting particles is disposed on the first to third sub-pixels SPX1, SPX2, and SPX3, respectively, thereby displaying a full-color image.

The first color converting layer CCL1 may include first color converting particles that convert light of the third color emitted from the light emitting element LD into light of the first color. For example, the first color converting layer CCL1 may include first quantum dots QD1 dispersed in one matrix material such as a base resin.

According to an embodiment, in case that the light emitting element LD is a blue light emitting element that emits blue light and the first sub-pixel SPX1 is a red pixel, the first color converting layer CCL1 may include a first quantum dot QD1 that converts blue light emitted from the blue light emitting element into red light. The first quantum dot QD1 may absorb blue light to shift a wavelength according to an energy transition to emit red light. In case that the first sub-pixel SPX1 is a pixel of a different color, the first color converting layer CCL1 may include a first quantum dot QD1 corresponding to a color of the first sub-pixel SPX1.

The second color converting layer CCL2 may include second color converting particles that convert light of the third color emitted from the light emitting element LD into light of the second color. For example, the second color converting layer CCL2 may include second quantum dots QD2 dispersed in one matrix material such as a base resin.

According to an embodiment, in case that the light emitting element LD is a blue light emitting element that emits blue light and the second sub-pixel SPX2 is a green pixel, the second color converting layer CCL2 may include a second quantum dot QD2 that converts blue light emitted from the blue light emitting element into green light. The second quantum dot QD2 may absorb blue light to shift a wavelength according to an energy transition to emit green light. In case that the second sub-pixel SPX2 is a pixel of a different color, the second color converting layer CCL2 may include a second quantum dot QD2 corresponding to a color of the second sub-pixel SPX2.

According to an embodiment, blue light having a relatively short wavelength among the visible ray bands is incident on the first quantum dot QD1 and the second quantum dot QD2, respectively, thereby increasing absorption coefficient of the first quantum dot QD1 and the second quantum dot QD2. Accordingly, the efficiency of light emitted from the first sub-pixel SPX1 and the second sub-pixel SPX2 may be finally increased, and at the same time, the excellent color reproducibility may be secured. The light emitting unit EMU of the first to third sub-pixels SPX1, SPX2, and SPX3 may use the light emitting elements LD of a same color (for example, the blue color light emitting element), thereby increasing the manufacturing efficiency of the display device DD.

The scattering layer LSL may be provided to efficiently use the third color (or blue color) light emitted from the light emitting element LD. For example, in case that the light emitting element LD is a blue light emitting element that emits blue light and the third sub-pixel SPX3 is a blue pixel, the scattering layer LSL may include at least one type of scatterer SCT to efficiently use the light emitted from the light emitting element LD. For example, the scatterer SCT of the scattering layer LSL may include one or more of a barium sulfate (BaSO+), a calcium carbonate (CaCO₃), a titanium oxide (TiO₂), a silicon oxide (SiO₂), an aluminum oxide (Al₂O₃), a zirconium oxide (ZrO₂), and a zinc oxide (ZnO). The scatterer SCT is not disposed only in the third sub-pixel SPX3, and may be selectively included in the first color converting layer CCL1 or the second color converting layer CCL2. According to an embodiment, the scatterer SCT may be omitted and the scattering layer LSL including a transparent polymer may be provided.

A first capping layer CPL1 may be disposed on the color converting layer CCL. The first capping layer CPL1 may be entirely disposed on the first to third sub-pixels SPX1, SPX2, and SPX3. The first capping layer CPL1 may cover the color converting layer CCL. The first capping layer CPL1 may prevent impurities such as moisture or air from penetrating from the outside to damage or contaminate the color converting layer CCL.

The first capping layer CPL1, which is an inorganic layer, may include one or more of a silicon nitride (SiNₓ), an aluminum nitride (AlNₓ), a titanium nitride (TiNₓ), a silicon oxide (SiOₓ), an aluminum oxide (AlOₓ), a titanium oxide (TiOₓ), a silicon oxycarbide (SiOₓC_{y}), and a silicon oxynitride (SiOₓN_{y}).

An optical layer OPL may be disposed on the first capping layer CPL1. The optical layer OPL may serve to improve light extraction efficiency by recycling light provided from the color converting layer CCL by total reflection. To this end, the optical layer OPL may have a relatively low refractive index compared to the color converting layer CCL. For example, the refractive index of the color converting layer CCL may be about 1.6 to 2.0, and the refractive index of the optical layer OPL may be about 1.1 to 1.3.

A second capping layer CPL2 may be disposed on the optical layer OPL. The second capping layer CPL2 may be entirely disposed on the first to third sub-pixels SPX1, SPX2, and SPX3. The second capping layer CPL2 may cover the optical layer OPL. The second capping layer CPL2 may prevent impurities such as moisture or air from penetrating from the outside to damage or contaminate the optical layer OPL.

The second capping layer CPL2, which is an inorganic layer, may include one or more of a silicon nitride (SiNₓ), an aluminum nitride (AlNₓ), a titanium nitride (TiNₓ), a silicon oxide (SiOₓ), an aluminum oxide (AlOₓ), a titanium oxide (TiOₓ), a silicon oxycarbide (SiOₓC_{y}), and a silicon oxynitride (SiOₓN_{y}).

A planarization layer PLL may be disposed on the second capping layer CPL2. The planarization layer PLL may be entirely provided in the first to third sub-pixels SPX1, SPX2, and SPX3.

The planarization layer PLL may include an organic material such as an acrylic resin, an epoxy resin, a phenol resin, a polyamide resin, a polyimide rein, a polyester resin, a polyphenylenesulfide resin, or a benzocyclobutene. However, it is not necessarily limited thereto, and the planarization layer PLL may include a silicon oxide (SiOₓ), a silicon nitride (SiNₓ), a silicon oxynitride (SiOₓN_{y}), an aluminum nitride (AlNₓ), an aluminum oxide (AlOₓ), a zirconium oxide (ZrOₓ), a hafnium oxide (HfOₓ), or a titanium oxide (TiOₓ), and various types of inorganic materials.

A color filter layer CFL may be disposed on the planarization layer PLL. The color filter layer CFL may include color filters CF1, CF2, and CF3 matching the color of each pixel PXL. A full-color image may be displayed by disposing the color filters CF1, CF2, and CF3 matching respective colors of the first to third sub-pixels SPX1, SPX2, and SPX3.

The color filter layer CFL may include the first color filter CF1 that is disposed in the first sub-pixel SPX1 to selectively transmit light emitted by the first sub-pixel SPX1, the second color filter CF2 that is disposed in the second sub-pixel SPX2 to selectively transmit light emitted by the second sub-pixel SPX2, and the third color filter CF3 that is disposed in the third sub-pixel SPX3 to selectively transmit light emitted by the third sub-pixel SPX3.

According to an embodiment, the first color filter CF1, the second color filter CF2, and the third color filter CF3 may be a red color filter, a green color filter, and a blue color filter respectively, but the disclosure is not limited necessarily thereto. Hereinafter, in case that referring to one of the first color filter CF1, the second color filter CF2, and the third color filter CF3, or in case that comprehensively referring to two or more thereof, it will be referred to as the “color filter CF” or “color filters CF”.

The first color filter CF1 may overlap the first color converting layer CCL1 in the thickness direction (for example, the third direction DR3) of the base layer BSL. The first color filter CF1 may include a color filter material that selectively transmits light of a first color (or red color). For example, in case that the first sub-pixel SPX1 is a red pixel, the first color filter CF1 may include a red color filter material.

The second color filter CF2 may overlap the second color converting layer CCL2 in the thickness direction (for example, the third direction DR3) of the base layer BSL. The second color filter CF2 may include a color filter material that selectively transmits light of a second color (or green color). For example, in case that the second sub-pixel SPX2 is a green pixel, the second color filter CF2 may include a green color filter material.

The third color filter CF3 may overlap the scattering layer LSL in the thickness direction (for example, the third direction DR3) of the base layer BSL. The third color filter CF3 may include a color filter material that selectively transmits light of a third color (or blue color). For example, in case that the third sub-pixel SPX3 is a blue pixel, the third color filter CF3 may include a blue color filter material.

According to an embodiment, a light blocking layer BM may be further disposed between the first to third color filters CF1, CF2, and CF3, and, in case that the light blocking layer BM is formed between the first to third color filters CF1, CF2, and CF3, it is possible to prevent a color mixing defect viewed from a front or side of a display device DD. A material of the light blocking layer BM is not particularly limited, and may be made of various light blocking materials. For example, the light blocking layer BM may include a black matrix, or may be implemented by stacking the first to third color filters CF1, CF2, and CF3 on each other.

An overcoat layer OC may be disposed on the color filter layer CFL. The overcoat layer OC may be entirely provided in the first to third sub-pixels SPX1, SPX2, and SPX3. The overcoat layer OC may cover the color filter layer CFL and a lower member thereof. The overcoat layer OC may prevent moisture or air from penetrating into the above-mentioned lower members that are disposed therebelow. The overcoat layer OC may protect the above-mentioned lower members from foreign matters such as dust.

The overcoat layer OC may include an organic material such as an acrylic resin, an epoxy resin, a phenol resin, a polyamide resin, a polyimide rein, a polyester resin, a polyphenylenesulfide resin, or a benzocyclobutene. However, it is not necessarily limited thereto, and the overcoat layer OC may include a silicon oxide (SiOₓ), a silicon nitride (SiNₓ), a silicon oxynitride (SiOₓN_{y}), an aluminum nitride (AlNₓ), an aluminum oxide (AlOₓ), a zirconium oxide (ZrOₓ), a hafnium oxide (HfOₓ), or a titanium oxide (TiOₓ), and various types of inorganic materials.

An outer film layer OFL may be disposed on the overcoat layer OC. The outer film layer OFL may be disposed at an outer side of the display device DD to reduce external influence. The outer film layer OFL may be entirely provided in the first to third sub-pixels SPX1, SPX2, and SPX3. According to an embodiment, the outer film layer OFL may include one of a polyethyleneterephthalate (PET) film, a low reflective film, a polarization film, and a transmittance controllable film, but is not necessarily limited thereto. According to an embodiment, the pixel PXL may include an upper substrate rather than the outer film layer OFL.

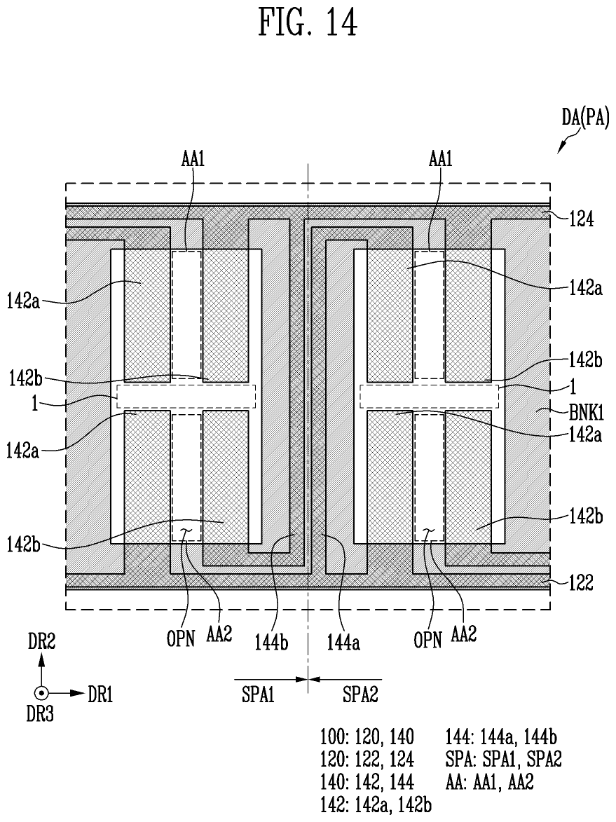

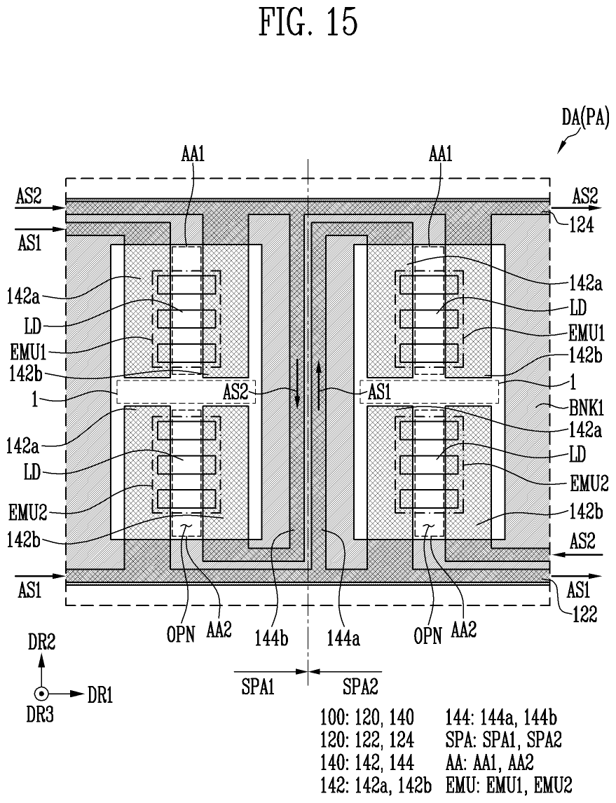

Hereinafter, a manufacturing method of the display device DD according to an embodiment will be described with reference to FIG. 14 and FIG. 15. Descriptions that may be redundant to those described above are simplified or are not repeated.

FIG. 14 and FIG. 15 illustrate schematic top plan views of process steps of a manufacturing method of a display device according to an embodiment. FIG. 14 and FIG. 15 may illustrate a process procedure of forming the pixel circuit layer PCL and the light emitting element layer EML. FIG. 14 and FIG. 15 illustrate an embodiment described above with reference to FIG. 7 to FIG. 9.

Referring to FIG. 14, the electrodes 100 and the first bank BNK1 may be formed (or disposed) on the pixel circuit layer PCL including the base layer BSL.

According to an embodiment, electrodes (or wires) and insulating films disposed on the base layer BSL may be formed by patterning a conductive layer (or metal layer), an inorganic material, or an organic material by performing a process by using a mask.

In this step, the electrodes 100 may be patterned in one area or an area. After the electrodes 100 are deposited on the base layer BSL (or the pixel circuit layer PCL) by various methods such as sputtering, they may be patterned by using a mask.

For example, the first body electrode 122 and the second body electrode 124 may be patterned to extend along the first direction DR1 across the sub-alignment areas SPA (for example, the first sub-alignment area SPA1 and the second sub-alignment area SPA2). The branch electrodes 140 may be disposed between the first body electrode 122 and the second body electrode 124, and at least some of the adjacent electrodes 142 may be patterned in the opening OPN surrounded by the first bank BNK1. The connecting branch electrodes 144 may electrically connect the adjacent electrodes 142 of the sub-alignment areas SPA adjacent to each other.

In this step, the first body electrode 122, the first adjacent electrode 142a, and the first connecting branch electrode 144a may be integrally patterned with each other to be electrically connected to each other. The second body electrode 124, the second adjacent electrode 142b, and the second connecting branch electrode 144b may be integrally patterned with each other to be electrically connected to each other.

In this step, the first connecting branch electrode 144a may be patterned to electrically connect the first adjacent electrodes 142a of each of the sub-alignment areas SPA adjacent to each other. The second connecting branch electrode 144b may be patterned to electrically connect the second adjacent electrodes 142b of each of the sub-alignment areas SPA adjacent to each other.

In this step, the adjacent electrodes 142 are spaced apart from each other along the first direction DR1 in each sub-alignment area SPA, so that two or more pathway areas AA may be defined.

In this step, the open area 1 may be disposed between the adjacent electrodes 142 adjacent to each other along the first direction DR1. For example, the adjacent electrodes 142 substantially formed at the upper side may be spaced apart from the adjacent electrodes 142 substantially formed at the lower side with the open area 1 interposed therebetween.

According to an embodiment, the first adjacent electrode 142a, the first connecting branch electrode 144a, and the first body electrode 122 may be integral. The second adjacent electrode 142b, the second connecting branch electrode 144b, and the second body electrode 124 may be integral.

Referring to FIG. 15, the light emitting elements LD may be aligned in the pathway area AA within each sub-alignment area SPA. The light emitting elements LD may be disposed on some (for example, the adjacent electrodes 142) of the electrodes 100.

The ink including the light emitting elements LD may be supplied into the opening OPN in which a fluid defined by the first bank BNK1 may be accommodated. For example, the ink including the light emitting elements LD and a solvent may be supplied onto the base layer BSL by a printing device that ejects a fluid. According to an embodiment, the solvent may include an organic solvent. For example, the solvent may be one of propylene glycol methyl ether acetate (PGMEA), dipropylen glycol n-propyl ether (DGPE), and triethylene gylcol n-butyl ether (TGBE). However, the disclosure is not limited to the example described above.

In this step, the ink may be accommodated in the space defined by the first bank BNK1, alignment signals may be supplied to the electrodes 100, and the light emitting elements LD may be aligned based on an electric field according to the alignment signals. The first alignment signal AS1 is supplied to the first adjacent electrode 142a, the first connecting branch electrode 144a, and the first body electrode 122, and the second alignment signal AS2 is supplied to the second adjacent electrode 142b, the second connecting branch electrode 144b, and the second body electrode 124, so that the light emitting elements LD may be aligned between the first adjacent electrode 142a and the second adjacent electrode 142b. The solvent may be removed.

According to an embodiment, the same alignment signal may be applied to the adjacent electrodes 142 adjacent along the second direction DR2 with the open area 1 interposed therebetween. Accordingly, the light emitting elements LD may not be further aligned in the open area 1. For example, the first alignment signal may be applied to the first adjacent electrodes 142a adjacent to each other along the second direction DR2, and the second alignment signal may be applied to the second adjacent electrodes 142b adjacent to each other along the second direction DR2.

In this step, the light emitting elements LD may not be substantially supplied (or aligned) into the open area 1, and thus a risk in which the light emitting elements LD may be disposed in an area in which light cannot be emitted is prevented, and the process costs may be substantially reduced.

After that, although separate drawings are not shown, the connecting electrodes CNE may be patterned, and the light emitting elements LD may receive electrical signals for emitting light. The color converting layer CCL and the color filter layer CFL may be formed thereafter.

While the disclosure has been shown and described with reference to embodiments thereof, it will be understood by those skilled in the art that various changes in forms and details may be made therein without departing from the spirit and scope of the disclosure and as defined by the appended claims and their equivalents.

Therefore, the technical scope of the disclosure may be determined by the scope of the accompanying claims.

What is claimed is:

1. A display device comprising:
electrodes disposed on a base layer and including:
a body electrode and a branch electrode electrically connected to the body electrode, the branch electrode including adjacent electrodes including a first adjacent electrode and a second adjacent electrode; and
light emitting elements disposed in an alignment area including sub-alignment areas disposed on the base layer and disposed between the first adjacent electrode and the second adjacent electrode, wherein
each of the sub-alignment areas includes a pathway area defined by the first adjacent electrode and the second adjacent electrode spaced apart from each other in a first direction,
the pathway area includes a first pathway area and a second pathway area spaced apart from each other in a second direction different from the first direction,
the first adjacent electrode of the first pathway area and the first adjacent electrode of the second pathway area are spaced apart from each other with an open area between the first adjacent electrode of the first pathway area and the first adjacent electrode of the second pathway area, and
the second adjacent electrode of the first pathway area and the second adjacent electrode of the second pathway area are spaced apart from each other with the open area between the second adjacent electrode of the first pathway area and the second adjacent electrode of the second pathway area.

2. The display device of claim 1, wherein
the alignment area extends in the first direction, and
the alignment area includes a first alignment area and a second alignment area adjacent to each other in the second direction.

3. The display device of claim 2, wherein
the body electrode in the first alignment area and the body electrode in the second alignment area are separated from each other.

4. The display device of claim 2, wherein
the sub-alignment areas include a first sub-alignment area and a second sub-alignment area,
the branch electrode includes a connecting branch electrode electrically connecting the adjacent electrode in the first sub-alignment area and the adjacent electrode in the second sub-alignment area,
the connecting branch electrode includes a first connecting branch electrode and a second connecting branch electrode,
the body electrode includes a first body electrode and a second body electrode,
the first body electrode, the first adjacent electrode, and the first connecting branch electrode are integral with each other, and
the second body electrode, the second adjacent electrode, and the second connecting branch electrode are integral with each other.

5. The display device of claim 4, wherein
the first connecting branch electrode electrically connects the first adjacent electrode and the first body electrode disposed in the first pathway area in the second sub-alignment area, and
the second connecting branch electrode electrically connects the second adjacent electrode and the second body electrode disposed in the second pathway area in the first sub-alignment area.

6. The display device of claim 4, further comprising:
a bank surrounding at least a portion of the pathway area and overlapping the connecting branch electrode in a plan view,
wherein the open area does not overlap the bank in a plan view.

7. The display device of claim 1, wherein:
the sub-alignment areas include a first sub-alignment area and a second sub-alignment area adjacent to each other in the first direction;
the light emitting element includes first light emitting elements disposed in the first pathway area to form a first light emitting part and second light emitting elements disposed in the second pathway area to form a second light emitting part;
the light emitting element in the first sub-alignment area and the light emitting element in the second sub-alignment area form a sub-pixel;
the display device further includes an anode connecting electrode, a first intermediate connecting electrode, a second intermediate connecting electrode, a third intermediate connecting electrode, and a cathode connecting electrode; and
the anode connecting electrode, the first light emitting part in the first sub-alignment area, the first intermediate connecting electrode, the second light emitting part in the first sub-alignment area, the second intermediate connecting electrode, the second light emitting part in the second sub-alignment area, the third intermediate connecting electrode, the first light emitting part in the second sub-alignment area, and the cathode connecting electrode are sequentially electrically connected.

8. The display device of claim 7, wherein
the first intermediate connecting electrode overlaps the open area in the first sub-alignment area in a plan view, and
the third intermediate connecting electrode overlaps the open area in the second sub-alignment area in a plan view.

9. The display device of claim 1, wherein
the open area does not overlap the light emitting element in a plan view.

10. The display device of claim 1, further comprising:
sub-pixels each including the light emitting element, wherein
the sub-alignment areas include a first sub-alignment area and a second sub-alignment area adjacent to each other in the first direction, and
the first sub-alignment area and the second sub-alignment area correspond to one of the sub-pixels.

11. The display device of claim 1, further comprising:
a first sub-pixel emitting light of a first color and a second sub-pixel emitting light of a second color, each of the first sub-pixel and the second sub-pixel including the light emitting element, wherein
the sub-alignment areas include a first sub-alignment area and a second sub-alignment area adjacent to each other in the first direction,
the first sub-alignment area corresponds to the first sub-pixel, and
the second sub-alignment area corresponds to the second sub-pixel.

12. The display device of claim 1, wherein
the body electrode extends in the first direction from a first end portion of the light emitting element toward a second end portion of the light emitting element, and
the adjacent electrode extends in the second direction.

13. A display device comprising:
alignment areas including a first alignment area and a second alignment area that extend in a first direction and are spaced apart from each other in a second direction different from the first direction;
electrodes including body electrodes and branch electrodes electrically connected to the body electrodes, at least part of the electrodes being disposed within the alignment areas; and
light emitting elements disposed in the alignment areas, wherein
the body electrodes extend in the first direction,
the body electrodes in the first alignment area and the body electrodes in the second alignment area are separated from each other, and
the branch electrodes include connecting branch electrodes extending in the second direction.

14. A manufacturing method of a display device, comprising:
patterning electrodes including body electrodes and branch electrodes disposed on a base layer; and
disposing a light emitting element on an adjacent one of the branch electrodes in an alignment area, wherein
the alignment area includes sub-alignment areas;
each of the sub-alignment areas includes a first pathway area and a second pathway area;
the adjacent electrode includes a first adjacent electrode and a second adjacent electrode;
the first adjacent electrode of the first pathway area and the first adjacent electrode of the second pathway area are spaced apart from each other with an open area between the first adjacent electrode of the first pathway area and the first adjacent electrode of the second pathway area; and
the second adjacent electrode of the first pathway area and the second adjacent electrode of the second pathway area are spaced apart from each other with the open area between the second adjacent electrode of the first pathway area and the second adjacent electrode of the second pathway.

15. The manufacturing method of the display device of claim 14, wherein
the body electrodes include a first body electrode and a second body electrode,
the first body electrode is electrically connected to the first adjacent electrode,
the second body electrode is electrically connected to the second adjacent electrode, and
the disposing of the light emitting element includes:
applying a first alignment signal to the first adjacent electrode through the first body electrode; and
applying a second alignment signal to the second adjacent electrode through the second body electrode.

16. The manufacturing method of the display device of claim 15, wherein
the sub-alignment areas include a first sub-alignment area and a second sub-alignment area adjacent in a first direction, and
the body electrodes are disposed throughout the first sub-alignment area and the second sub-alignment area in the first direction.

17. The manufacturing method of the display device of claim 16, further comprising:
forming a bank protruding in a thickness direction of the base layer on the base layer, wherein
the branch electrodes further includes a connecting branch electrode electrically connecting the adjacent electrode in the first sub-alignment area and the adjacent electrode in the second sub-alignment area,
the open area does not overlap the bank in a plan view, and
the connecting branch electrode overlaps the bank in a plan view.

18. The manufacturing method of the display device of claim 14, wherein
the disposing of the light emitting element includes aligning the light emitting element based on an electric field between the first adjacent electrode and the second adjacent electrode, and
the aligning of the light emitting element includes aligning the light emitting element between the first adjacent electrode and the second adjacent electrode without aligning the light emitting element in the open area.

19. The manufacturing method of the display device of claim 18, wherein
the first adjacent electrode and the second adjacent electrode are spaced apart from each other in the first direction,
the first pathway area and the second pathway area are spaced apart from each other in a second direction different from the first direction,
a first alignment signal is applied to the first adjacent electrode of the first pathway area and the first adjacent electrode of the second pathway area, and
a second alignment signal is applied to the second adjacent electrode of the first pathway area and the second adjacent electrode of the second pathway area.

20. The manufacturing method of the display device of claim 14, further comprising:
forming a connecting electrode layer,
wherein the connecting electrode layer includes:
an anode connecting electrode electrically connected to the light emitting element;
an intermediate connecting electrode electrically connected to the light emitting element and overlapping the open area in a plan view; and
a cathode connecting electrode electrically connected to the light emitting element.
